(19) United States
(12) Patent Application Publication
(10) Pub. No.: US 2026/0231618 A1
(43) Pub. Date: Aug. 6, 2026

(54) DISPLAY DEVICE, ELECTRONIC DEVICE INCLUDING THE SAME AND METHOD FOR FABRICATING THE DISPLAY DEVICE

(71) Applicant: Samsung Display Co., LTD., Yongin-si (KR)

(72) Inventors: Jong Hee PARK, Yongin-si (KR); Hee Jun YANG, Yongin-si (KR)

(21) Appl. No.: 19/316,525

(22) Filed: Sep. 2, 2025

(30) Foreign Application Priority Data
Jan. 31, 2025 (KR) 10-2025-0012405

(51) Int. Cl. H10K 59/122; H10K 59/12; H10K 59/80

(52) U.S. Cl. CPC H10K 59/122; H10K 59/1201; H10K 59/873

(57) ABSTRACT

A display device includes a display device including a substrate including a light-emitting area and a non-light-emitting area; a via layer disposed on the substrate and including an organic material; a bank structure disposed on the via layer in a portion overlapping the light-emitting area and having an overhang structure; an element insulating layer disposed on the bank structure and defining a light-emitting opening; and a first light-emitting element disposed on the element insulating layer and in contact with the bank structure, where a via hole penetrates through a first bank layer of the bank structure in a portion overlapping the non-light-emitting area, the via hole defines a non-light-emitting opening, and the via hole exposes the via layer in a portion overlapping the non-light-emitting opening.

This application claims priority to Korean Patent Application No. 10-2025-0012405, filed on Jan. 31, 2025, and all the benefits accruing therefrom under 35 U.S.C. § 119, the content of which in its entirety is herein incorporated by reference.

### BACKGROUND

### 1. Field

The disclosure relates to a display device, an electronic device using the same, and a method for fabricating the display device.

### 2. Description of the Related Art

As an information society develops, the demand for a display device for displaying an image is increasing in various forms. In an embodiment, the display device is being applied to various electronic devices such as smartphones, digital cameras, laptop computers, navigation devices, and smart televisions. The display device may be a flat panel display device such as a liquid crystal display device, a field emission display device, or an organic light-emitting display device. Among the flat panel display devices, the light-emitting display device may include a light-emitting element in which each of the pixels of a display panel may emit light by itself, thereby displaying an image without a backlight unit providing the light to the display panel.

### SUMMARY

Features of the disclosure provide a display device capable of providing a relatively high resolution image, an electronic device using the display device, and a method for fabricating the display device.

Features of the disclosure provide a display device capable of solving reliability problems caused by outgas of an organic via layer, an electronic device using the same, and a method for fabricating the display device.

However, features of the disclosure are not restricted to those set forth herein. The above and other features of the disclosure will become more apparent to one of ordinary skill in the art to which the disclosure pertains by referencing the detailed description of the disclosure given below.

Details of other embodiments are included in the detailed description and drawings.

In an embodiment of the disclosure, a display device including a substrate including a light-emitting area and a non-light-emitting area; a via layer disposed on the substrate and including an organic material; a bank structure disposed on the via layer in a portion overlapping the light-emitting area and having an overhang structure; an element insulating layer disposed on the bank structure and defining a light-emitting opening; and a first light-emitting element disposed on the element insulating layer and in contact with the bank structure, where a via hole penetrates through a first bank layer of the bank structure in a portion overlapping the non-light-emitting area, the via hole defines a non-light-emitting opening, and the via hole exposes the via layer in a portion overlapping the non-light-emitting opening.

In an embodiment, the bank structure may further include a second bank layer disposed on the first bank layer; and a third bank layer including a tip that protrudes further toward the non-light-emitting area than a side surface of the second bank layer.

In an embodiment, in a plan view, the first bank layer has a shape of a conductive pattern completely surrounding the non-light-emitting opening.

In an embodiment, the display device may further include a second light-emitting element spaced apart from the first light-emitting element, where the second bank layer and the third bank layer overlapping the first light-emitting element and the second bank layer and the third bank layer overlapping the second light-emitting element are spaced apart from each other with the via hole.

In an embodiment, the second bank layer and the third bank layer overlapping the first light-emitting element and the second bank layer and the third bank layer overlapping the second light-emitting element may be electrically connected through the first bank layer.

In an embodiment, the display device may further include a first element inorganic layer covering the first light-emitting element; and a second element inorganic layer covering the second light-emitting element, where the first element inorganic layer and the second element inorganic layer are spaced apart from each other with the via hole.

In an embodiment, the display device may further include an organic encapsulation layer disposed on the first element inorganic layer and the second element inorganic layer, where the via layer may contact the organic encapsulation layer in a portion overlapping the via hole.

In an embodiment, the second bank layer may include a first surface facing the first bank layer; a first side surface facing the via hole; and a second side surface opposite to the first side surface, and a first inclined angle defined by the first surface and the first side surface and a second inclined angle defined by the first surface and the second side surface are different from each other.

In an embodiment, the first inclined angle may be greater than the second inclined angle.

In an embodiment, the display device may further include an insulating layer disposed between the via layer and the bank structure and including an inorganic insulating material, where the via hole penetrates through the insulating layer, the insulating layer, the first bank layer, and the third bank layer facing the via hole have a regular tapered shape, and a taper angle of the insulating layer, the first bank layer, and the third bank layer facing the via hole may be 60 degrees or more and 80 degrees or less.

In an embodiment of the disclosure, a method for fabricating a display device, the method including: forming a bank structure including a first bank layer, a second bank layer, and a third bank layer on a substrate including a via layer; forming a tip of the third bank layer that protrudes further than a side surface of the second bank layer; forming a light-emitting element and an element inorganic layer on the bank structure; and defining a via hole by removing a portion of the bank structure, where the via hole penetrates through the first bank layer.

In an embodiment, in the defining the via hole by removing the portion of the bank structure, the via hole is defined by removing a portion of the first bank layer by a dry etching process.

In an embodiment, in the defining the via hole by removing the portion of the bank structure, the dry etching process may be performed using a halftone mask.

In an embodiment, in the defining the via hole by removing the portion of the bank structure, in a plan view, a plurality of via holes may be formed and each have an island shape.

In an embodiment, in the forming the tip of the third bank layer that protrudes further than the side surface of the second bank layer, the second bank layer and the third bank layer include different metal materials, and the second bank layer may have a higher etching rate than the first bank layer and the third bank layer.

In an embodiment of the disclosure, an electronic device include at least one display device including a substrate including a light-emitting area and a non-light-emitting area; and at least one of a display module, a processor, a memory, and a power module connected to the display device, where the at least one display device includes: a via layer disposed on the substrate and including an organic material; a bank structure disposed on the via layer in a portion overlapping the light-emitting area and having an overhang structure; an element insulating layer disposed on the bank structure and defining a light-emitting opening; and a first light-emitting element disposed on the element insulating layer and in contact with the bank structure, where a via hole penetrates through a first bank layer of the bank structure in a portion overlapping the non-light-emitting area, the via hole defines a non-light-emitting opening, and the via hole exposes the via layer in a portion overlapping the non-light-emitting opening.

According to the display device, the electronic device using the same, and the method for fabricating the display device in the embodiments, a display device capable of providing a high-resolution image and solving reliability problems caused by outgas of the organic via layer by forming a pore in the organic via layer, an electronic device using the same, and a method for fabricating the display device may be provided.

However, the effects of the embodiments are not restricted to the one set forth herein. The above and other effects of the embodiments will become more apparent to one of daily skill in the art to which the embodiments pertain by referencing the claims.

### BRIEF DESCRIPTION OF THE DRAWINGS

The above and other advantages and features of the disclosure will become more apparent by describing in detail embodiments thereof with reference to the attached drawings, in which:

FIG. 1 is a perspective view illustrating an embodiment of a display device;

FIG. 2 is a cross-sectional view illustrating an embodiment of the display device;

FIG. 3 is a plan view illustrating an embodiment of a display layer of the display device;

FIG. 4 is a plan view illustrating an embodiment of an arrangement of a plurality of pixels disposed in a display area in FIG. 3;

FIG. 5 is a cross-sectional view illustrating an embodiment of the display layer taken along line X1-X1′ of FIG. 4;

FIG. 6 is an enlarged cross-sectional view of area ‘A’ in FIG. 5;

FIG. 7 is an enlarged cross-sectional view of area ‘C’ in FIG. 6;

FIG. 8 is a cross-sectional view illustrating an embodiment of a display element layer taken along line X3-X3′ of FIG. 4;

FIG. 9 is a flowchart illustrating a fabricating process of forming a display element layer and a via hole in FIG. 5;

FIG. 10 is a cross-sectional view for describing operation S100 of FIG. 9;

FIGS. 11 to 13 are cross-sectional views for describing operation S200 of FIG. 9;

FIGS. 14 and 15 are cross-sectional views for describing operation S300 of FIG. 9;

FIGS. 16 to 19 are cross-sectional views for describing operation S400 of FIG. 9;

FIG. 20 is a cross-sectional view illustrating an embodiment of the display layer taken along line X5-X5′ of FIG. 4;

FIG. 21 is a flowchart illustrating a fabricating process of forming a display element layer and a via hole in FIG. 20;

FIG. 22 is a cross-sectional view for describing operation S500 of FIG. 21;

FIGS. 23 and 24 are cross-sectional views for describing operation S600 of FIG. 21;

FIGS. 25 to 29 are cross-sectional views for describing operation S700 of FIG. 21;

FIGS. 30 to 33 are cross-sectional views for describing operation S800 of FIG. 21;

FIG. 34 is a block diagram of an embodiment of an electronic device; and

FIG. 35 illustrates schematic diagrams of embodiments of electronic devices.

### DETAILED DESCRIPTION

Advantages and features of the disclosure and methods of accomplishing the same may be understood more readily by reference to the following detailed description of embodiments and the accompanying drawings. The disclosure may, however, be embodied in many different forms and should not be construed as being limited to the embodiments set forth herein. Rather, these embodiments are provided so that this disclosure will be thorough and complete and will fully convey the concept of the disclosure to those skilled in the art, and the disclosure will only be defined by the appended claims.

It will be understood that when an element or layer is referred to as being “on” another element or layer, the element or layer may be directly on another element or layer or intervening elements or layers. Like reference numerals refer to like elements throughout the specification. Shapes, sizes, ratios, angles, numbers, etc. disclosed in the drawings for describing embodiments are merely illustrative, and the disclosure is not limited to the illustrated details.

It will be understood that, although the terms first, second, third, etc., may be used herein to describe various elements, these elements should not be limited by these terms. These terms are only used to distinguish one element from another element. Thus, a first element discussed below could be termed a second element without departing from the teachings of the disclosure.

Features of various embodiments of the disclosure may be partially or entirely coupled to or combined with each other, and may be inter-operated and driven in technically various ways. The embodiments may be implemented independently from each other, or may be implemented together in a co-dependent relationship.

Hereinafter, illustrative embodiments will be described with reference to the accompanying drawings.

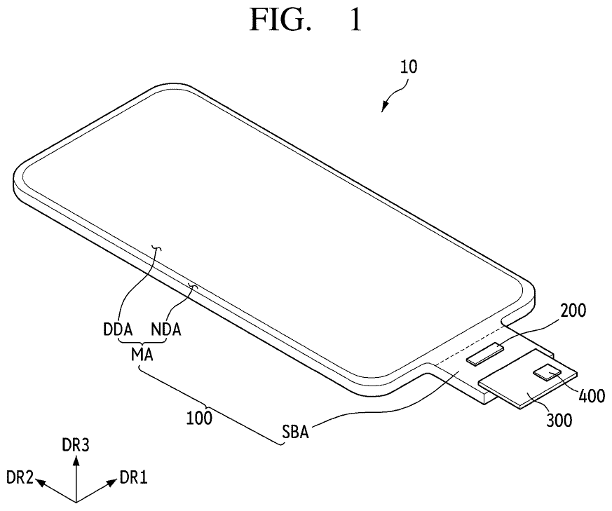

FIG. 1 is a perspective view illustrating an embodiment of a display device.

Referring to FIG. 1, a display device 10 may be applied to portable electronic devices such as a mobile phone, a smartphone, a tablet personal computer (“PC”), a mobile communication terminal, an electronic notebook, an electronic book, a portable multimedia player (“PMP”), navigation, and an ultra mobile PC (“UMPC”). In an embodiment, the display device 10 may be applied to a display unit of a television, a laptop computer, a monitor, a billboard, or the Internet of Things (“IoT”), for example. In another embodiment, the display device 10 may be applied to a wearable device such as a smart watch, a watch phone, a glasses-type display, and a head mounted display (“HMD”).

The display device 10 may be formed in a planar shape similar to a quadrangle. In an embodiment, the display device 10 may have a planar shape similar to a quadrangle having a short side in a first direction DR1 and a long side in a second direction DR2, for example. A corner where the short side in the first direction DR1 and the long side in the second direction DR2 meet may be rounded to have a predetermined curvature or may be formed at a right angle. The planar shape of the display device 10 is not limited to the quadrangle, and may be formed similarly to other polygons, circles, or ovals.

The display device 10 may include a display panel 100, a display driver 200, a circuit board 300, and a touch driver 400.

The display panel 100 may include a main area MA and a sub-area SBA. The main area MA may include a display area DDA including pixels displaying an image, and a non-display area NDA disposed around the display area DDA.

The display area DDA may emit light from a plurality of light-emitting areas or a plurality of openings to be described later. In an embodiment, the display panel 100 may include a pixel circuit including switching elements, an element insulating layer defining the light-emitting areas or the openings, and a self-light-emitting element, for example. In an embodiment, the self-light-emitting element may include, but is not limited to, at least one of an organic light-emitting diode (“LED”) including an organic light-emitting layer, a quantum dot LED including a quantum dot light-emitting layer, an inorganic LED including an inorganic semiconductor, and a micro LED, for example. In the following drawings, it is illustrated that the self-light-emitting element is an organic light-emitting diode.

The non-display area NDA may be an area outside the display area DDA. The non-display area NDA may be defined as an edge area of the main area MA of the display panel 100.

The sub-area SBA may be an area extending from one side of the main area MA. The sub-area SBA may include a flexible material that may be bent, folded, rolled, or the like. In an embodiment, when the sub-area SBA is bent, the sub-area SBA may overlap the main area MA in a thickness direction (e.g., a third direction DR3), for example. The sub-area SBA may include the display driver 200 and a pad portion connected to the circuit board 300. In another embodiment, the sub-area SBA may be omitted, and the display driver 200 and the pad portion may be disposed in the non-display area NDA.

The display driver 200 may output signals and voltages for driving the display panel 100. The display driver 200 may be formed as an integrated circuit (“IC”) and disposed (e.g., mounted) on the display panel 100 by a chip on glass (“COG”) method, a chip on plastic (“COP”) method, or an ultrasonic bonding method. In an embodiment, the display driver 200 may be disposed in the sub-area SBA, and may overlap the main area MA in the thickness direction by bending of the sub-area SBA, for example. In another embodiment, the display driver 200 may be disposed (e.g., mounted) on the circuit board 300.

The circuit board 300 may be attached onto the pad portion of the display panel 100 using an anisotropic conductive film (“ACF”). The circuit board 300 may be a flexible film such as a flexible printed circuit board, a printed circuit board, or a chip on film.

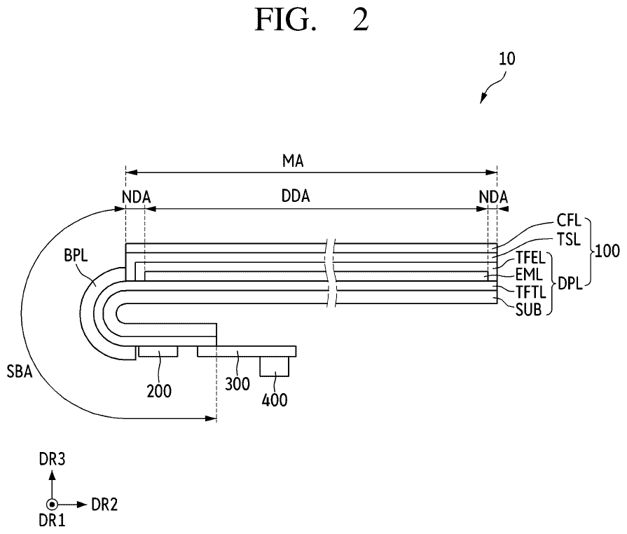

The touch driver 400 may be disposed (e.g., mounted) on the circuit board 300. The touch driver 400 may be connected to a touch sensor layer (‘TSL’ in FIG. 2) for sensing and driving a touch.

FIG. 2 is a cross-sectional view illustrating an embodiment of the display device.

Referring to FIG. 2, the display panel 100 may include a display layer DPL, a touch sensor layer TSL, and a color filter layer CFL. The display layer DPL may include a substrate SUB, a transistor layer TFTL, a display element layer EML, and a thin film encapsulation layer TFEL.

The substrate SUB may be a base substrate or a base member. The substrate SUB may be a flexible substrate that may be bent, folded, rolled, or the like. In an embodiment, the substrate SUB may include a polymer resin such as polyimide PI, for example, but is not limited thereto. In another embodiment, the substrate SUB may include a glass material or a metal material.

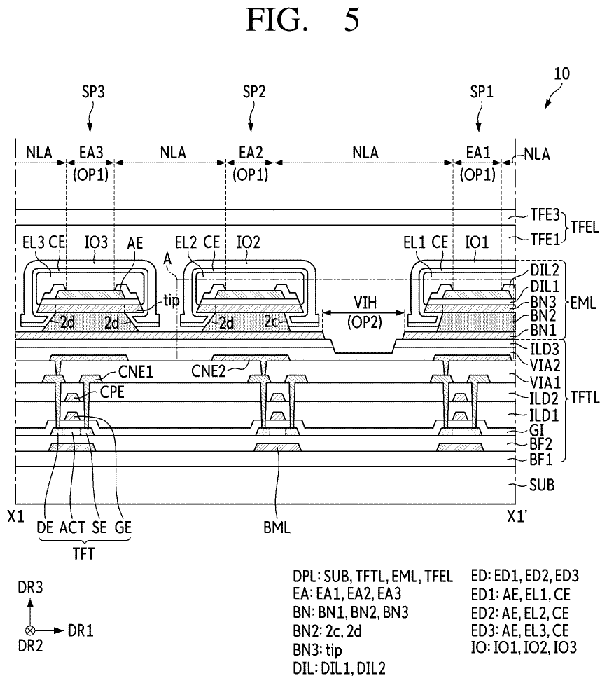

The transistor layer TFTL may be disposed on the substrate SUB. The transistor layer TFTL may be disposed in a portion overlapping the display area DDA, the non-display area NDA, and the sub-area SBA. The transistor layer TFTL may include a plurality of transistors (‘TFT’ in FIG. 5).

The display element layer EML may be disposed on the transistor layer TFTL. The display element layer EML may be disposed in a portion overlapping the display area DDA. The display element layer EML may include, but is not limited to, at least one of an organic light-emitting diode (“LED”) including an organic light-emitting layer, a quantum dot LED including a quantum dot light-emitting layer, an inorganic LED including an inorganic semiconductor, and a micro LED.

The thin film encapsulation layer TFEL may be disposed on the display element layer EML. The thin film encapsulation layer TFEL may be disposed in a portion overlapping the display area DDA and the non-display area NDA. The thin film encapsulation layer TFEL may cover upper and side surfaces of the display element layer EML, and may protect the display element layer EML from oxygen and moisture from the outside. The thin film encapsulation layer TFEL may include at least one inorganic film and at least one organic film for encapsulating the display element layer EML. In some embodiments, the thin film encapsulation layer TFEL may be omitted.

The touch sensor layer TSL may be disposed on the thin film encapsulation layer TFEL. The touch sensor layer TSL may be disposed in a portion overlapping the display area DDA and the non-display area NDA. The touch sensor layer TSL may sense a user's touch in a mutual capacitance method or a self-capacitance method. In some embodiments, the touch sensor layer TSL may be omitted.

The color filter layer CFL may be disposed on the touch sensor layer TSL. The color filter layer CFL may be disposed in a portion overlapping the display area DDA and the non-display area NDA. The color filter layer CFL may absorb a portion of light introduced from the outside of the display device 10 to reduce reflected light caused by external light. Therefore, the color filter layer CFL may prevent color distortion caused by reflection of external light.

As the color filter layer CFL is directly disposed on the touch sensor layer TSL, a separate substrate for the color filter layer CFL may not be desired in the display device 10. Therefore, the display device 10 may have a relatively small thickness. In some embodiments, the color filter layer CFL may also be omitted.

As illustrated in FIG. 2, a portion of the display panel 100 overlapping the sub-area SBA may be bent. When a portion of the display panel 100 is bent, the display driver 200, circuit board 300, and the touch driver 400 may overlap the main area MA in the third direction DR3.

When a portion of the display panel 100 is bent, a bending protection layer BPL may protect a lower structure overlapping the sub-area SBA from bending stress.

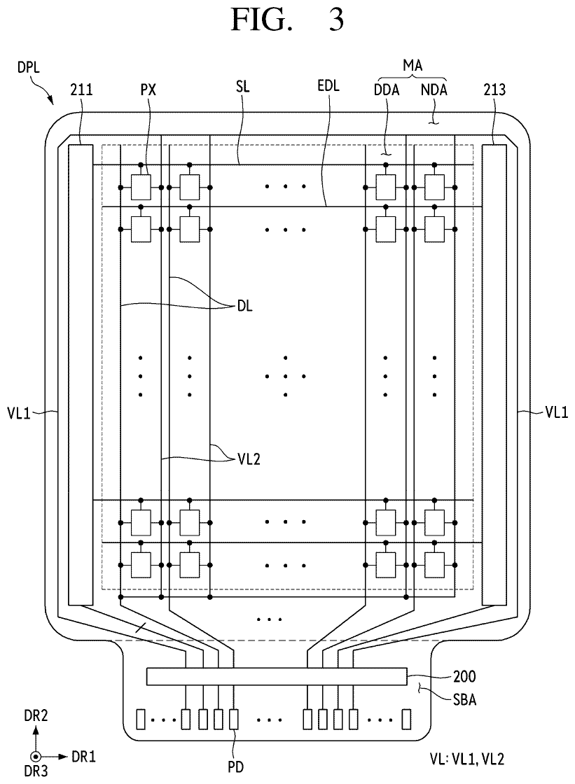

FIG. 3 is a plan view illustrating an embodiment of a display layer of the display device.

Referring to FIG. 3, the display layer DPL may include a plurality of pixels PX in a portion overlapping the display area DDA, and a plurality of power lines VL, a plurality of scan lines SL, a plurality of emission control lines EDL, and a plurality of data lines DL that are connected to the plurality of pixels PX.

The plurality of scan lines SL may each extend in the first direction DR1 and may be spaced apart from each other in the second direction DR2 intersecting the first direction DR1. The scan lines SL may be arranged along the second direction DR2. The scan lines SL may sequentially supply a scan signal to the plurality of pixels PX.

The emission control lines EDL may each extend in the first direction DR1 and may be spaced apart from each other in the second direction DR2. The emission control lines EDL may be arranged along the second direction DR2. The emission control lines EDL may sequentially supply a light-emitting signal to the plurality of pixels PX.

The data lines DL may extend in the second direction DR2 and may be spaced apart from each other in the first direction DR1. The data lines DL may be arranged along the first direction DR1. The data lines DL may supply a data voltage to the plurality of pixels PX. The data voltage may determine luminance of each of the plurality of pixels PX.

The power line VL may include a main power line VL1 and a sub-power line VL2. At least one of a first power voltage (high potential voltage) or a second power voltage (low potential voltage) may be transmitted to the sub-power line VL2 through the main power line VL1 overlapping the non-display area NDA. Hereinafter, the main power line VL1 and the sub-power line VL2 may be collectively referred to as the power line VL.

The non-display area NDA may surround the display area DDA. The non-display area NDA may include a scan driver 211 and an emission control driver 213.

The scan driver 211 may be disposed on the outside of one side of the display area DDA or on one side of the non-display area NDA. The scan driver 211 may include a plurality of driving transistors that generate gate signals based on a gate control signal.

The emission control driver 213 may be disposed on the outside of an opposite side of the display area DDA or on an opposite side of the non-display area NDA. The emission control driver 213 may include a plurality of emission control transistors that generate light-emitting signals based on an emission control signal.

The display layer DPL included in an embodiment may include a display driver 200 and a plurality of pad electrodes PD in a portion overlapping the sub-area SBA. The plurality of pad electrodes PD may be spaced apart from each other in the first direction DR1, and each pad electrode PD may be connected to each different line.

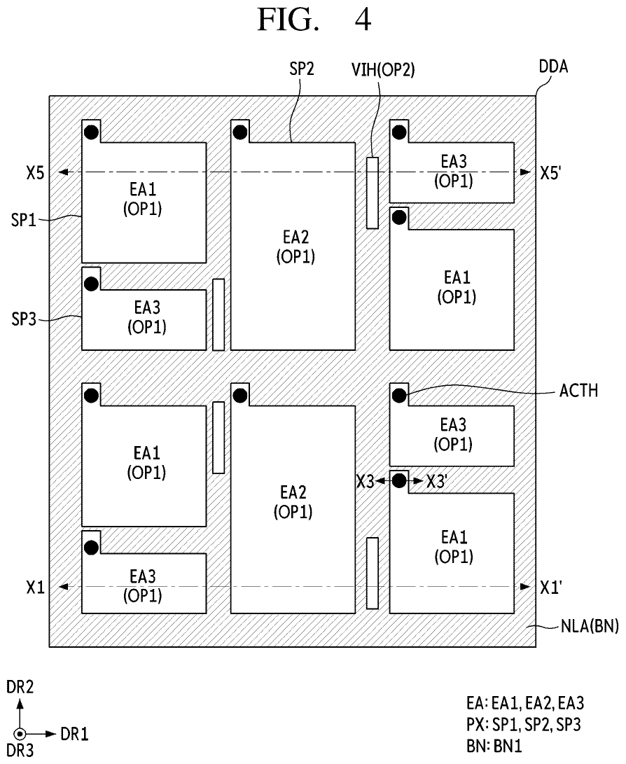

FIG. 4 is a plan view illustrating an arrangement of a plurality of pixels disposed in a display area in FIG. 3.

Referring to FIG. 4, a pixel PX in an embodiment may include a first sub-pixel SP1, a second sub-pixel SP2, and a third sub-pixel SP3 disposed in a portion overlapping the display area DDA. The first sub-pixel SP1, the second sub-pixel SP2, and the third sub-pixel SP3 may be spaced apart from each other.

The pixel PX may include a light-emitting area EA. The light-emitting area EA may be a portion from which light is emitted. In an embodiment, the first sub-pixel SP1 may include a first light-emitting area EA1, the second sub-pixel SP2 may include a second light-emitting area EA2, and the third sub-pixel SP3 may include a third light-emitting area EA3.

In an embodiment, the first light-emitting area EA1, the second light-emitting area EA2, and third light-emitting area EA3 may emit light of different colors. In an embodiment, the first light-emitting area EA1 may emit red light, the second light-emitting area EA2 may emit green light, and the third light-emitting area EA3 may emit blue light. However, this is only an illustrative embodiment, and the specification is not limited thereto.

In an embodiment, the light-emitting area EA may be defined by a light-emitting opening OP1. The light-emitting opening OP1 may be defined by a second element insulating layer (‘DIL2’ in FIG. 5) described later.

The display device 10 in an embodiment may include a non-light-emitting area NLA in a portion overlapping the display area DDA. The non-light-emitting area NLA may be disposed to surround each of the first light-emitting area EA1, the second light-emitting area EA2, and the third light-emitting area EA3. The non-light-emitting area NLA may prevent color mixing of light emitted from the first light-emitting area EA1, the second light-emitting area EA2, and the third light-emitting area EA3.

In an embodiment, a via hole VIH may be defined in a portion overlapping the non-light-emitting area NLA. A plurality of via holes VIH may be defined. The plurality of via holes VIH may be spaced apart from each other with each of the first to third light-emitting areas EA1, EA2, and EA3.

The via hole VIH may define a non-light-emitting opening OP2 in the portion overlapping the non-light-emitting area NLA. The non-light-emitting opening OP2 may not overlap the light-emitting opening OP1.

In plan view, the plurality of via holes VIH may be defined in an island shape. The plurality of via holes VIH may function as an outgas path for the organic material included in the display device 10.

A bank structure BN may be disposed in a portion overlapping the non-light-emitting area NLA. In plan view, the bank structure BN may be disposed to surround the light-emitting area EA and/or the light-emitting opening OP1.

The plurality of via holes VIH may be defined to penetrate through a first bank layer BN1 included in the bank structure BN. Accordingly, in a plan view, the first bank layer BN1 may have a form of a conductive pattern disposed to surround the plurality of via holes VIH.

In plan view, an anode contact hole ACTH may be defined in a portion overlapping the light-emitting area EA. For convenience of explanation, it is illustrated in the drawing that the anode contact hole ACTH is disposed on one side of the light-emitting area EA, but the specification is not limited thereto.

FIG. 5 is a cross-sectional view illustrating an embodiment of the display layer taken along line X1-X1′ of FIG. 4. FIG. 5 illustrates a cross-sectional structure of the first sub-pixel SP1, the second sub-pixel SP2, and the third sub-pixel SP3 in a portion overlapping the display area DDA of the display device 10.

Referring to FIG. 5, a transistor layer TFTL may be disposed on the substrate SUB. The transistor layer TFTL may include a first buffer layer BF1, a lower metal layer BML, a second buffer layer BF2, a transistor TFT, a gate insulating layer GI, a first insulating layer ILD1, a capacitor electrode CPE, a second insulating layer ILD2, a first connection electrode CNE1, a first via layer VIA1, a second connection electrode CNE2, a second via layer VIA2, and a third insulating layer ILD3.

The first buffer layer BF1 may be disposed on the substrate SUB. The first buffer layer BF1 may include an inorganic film capable of preventing permeation of air or moisture. In an embodiment, the first buffer layer BF1 may include a plurality of inorganic films alternately stacked, for example.

The lower metal layer BML may be disposed on the first buffer layer BF1. The lower metal layer BML may include a conductive metal and may be formed as, e.g., a single layer or a multi-layer including or consisting of any one of molybdenum (Mo), aluminum (Al), chromium (Cr), gold (Au), titanium (Ti), nickel (Ni), neodymium (Nd), and copper (Cu), or any alloys thereof.

The second buffer layer BF2 may cover the first buffer layer BF1 and the lower metal layer BML. The second buffer layer BF2 may include an inorganic film capable of preventing permeation of air or moisture. In an embodiment, the second buffer layer BF2 may include a plurality of inorganic films alternately stacked, for example.

The transistor TFT may be disposed on the second buffer layer BF2, and may constitute a pixel circuit. In an embodiment, the transistor TFT may be a driving transistor or a switching transistor of the pixel circuit.

The transistor TFT may include an active layer ACT, a source electrode SE, a drain electrode DE, and a gate electrode GE.

The active layer ACT may be disposed on the second buffer layer BF2. The active layer ACT may overlap the gate electrode GE in the third direction DR3 and may be insulated from the gate electrode GE by the gate insulating layer GI. The drain electrode DE and the source electrode SE may be portions formed by conducting a portion of the active layer ACT.

The gate insulating layer GI may be disposed on the active layer ACT. The gate insulating layer GI may cover the active layer ACT and the second buffer layer BF2, and may insulate the active layer ACT and the gate electrode GE from each other. The gate insulating layer GI may include a contact hole through which the first connection electrode CNE1 penetrates.

The gate electrode GE may be disposed on the gate insulating layer GI. The gate insulating layer GI may be disposed between the gate electrode GE and the active layer ACT.

The gate electrode GE may include a conductive metal and may be formed as a single layer or a multi-layer including or consisting of any one of molybdenum (Mo), aluminum (Al), chromium (Cr), gold (Au), titanium (Ti), nickel (Ni), neodymium (Nd), and copper (Cu), or any alloys thereof, for example.

The first insulating layer ILD1 may cover the gate electrode GE and the gate insulating layer GI. The first insulating layer ILD1 may include a contact hole through which the first connection electrode CNE1 penetrates. The contact hole of the first insulating layer ILD1 may be connected to the contact hole of the gate insulating layer GI and a contact hole of the second insulating layer ILD2.

The capacitor electrode CPE may be disposed on the first insulating layer ILD1. The capacitor electrode CPE may overlap the gate electrode GE in the third direction DR3. The capacitor electrode CPE and the gate electrode GE may form a capacitance.

The second insulating layer ILD2 may cover the capacitor electrode CPE and the first insulating layer ILD1. The second insulating layer ILD2 may include a contact hole through which the first connection electrode CNE1 penetrates. The contact hole of the second insulating layer ILD2 may be connected to the contact hole of the first insulating layer ILD1 and the contact hole of the gate insulating layer GI.

The first connection electrode CNE1 may be disposed on the second insulating layer ILD2. The first connection electrode CNE1 may electrically connect the drain electrode DE of the transistor TFT and the second connection electrode CNE2 to each other. The first connection electrode CNE1 may be inserted into the contact holes defined in the first insulating layer ILD1, the second insulating layer ILD2, and the gate insulating layer GI and contact the drain electrode DE of the transistor TFT.

The first via layer VIA1 may be disposed on the first connection electrode CNE1 and the second insulating layer ILD2. The first via layer VIA1 may planarize a lower structure. The first via layer VIA1 may include a contact hole through which the second connection electrode CNE2 penetrates.

The first via layer VIA1 may include an organic insulating material. In an embodiment, the first via layer VIA1 may include an acrylic resin, polyimide, polyamide, benzocyclobutene, a phenol resin, etc.

The second connection electrode CNE2 may be disposed on the first via layer VIA1. The second connection electrode CNE2 may be disposed in a portion overlapping the light-emitting area EA. The second connection electrode CNE2 may be inserted into the contact hole defined in the first via layer VIA1 and contact the first connection electrode CNE1.

The second via layer VIA2 may be disposed on the first via layer VIA1. The second via layer VIA2 may planarize a step formed by the second connection electrode CNE2.

The second via layer VIA2 may include an organic material. In an embodiment, the second via layer VIA2 may include an acrylic resin, a silicone resin, a silicone acrylic resin, an epoxy resin, polyimide, polyamide, benzocyclobutene, a phenol resin, etc.

The third insulating layer ILD3 may be disposed on the second via layer VIA2. The third insulating layer ILD3 may assist in preventing outgas caused by the organic material of the second via layer VIA2 from permeating into the display element layer EML.

The third insulating layer ILD3 may include an inorganic insulating material. In an embodiment, the third insulating layer ILD3 may include at least one of silicon nitride, silicon oxide, and silicon oxynitride.

The display element layer EML may be disposed on the transistor layer TFTL. The display element layer EML may include a bank structure BN, an element insulating layer DIL, a light-emitting element ED, and an element inorganic layer IO.

The bank structure BN may be disposed on the third insulating layer ILD3. The bank structure BN may be disposed in a portion overlapping the light-emitting area EA and/or the light-emitting opening OP1.

The bank structure BN may assist in positioning the first to third light-emitting elements ED1, ED2, and ED3 in portions overlapping the first to third light-emitting areas EA1, EA2, and EA3, respectively. In addition, the bank structure BN may assist in electrically connecting a cathode electrodes CE disposed to be spaced apart from each other in the first to third light-emitting areas EA1, EA2, and EA3.

The bank structure BN may include a first bank layer BN1, a second bank layer BN2, and a third bank layer BN3. The first bank layer BN1, the second bank layer BN2, and the third bank layer BN3 may be sequentially stacked in the third direction DR3.

The first bank layer BN1 may be disposed on the third insulating layer ILD3. The first bank layer BN1 may cover the third insulating layer ILD3 in a portion overlapping the light-emitting area EA and the non-light-emitting area NLA.

The first bank layer BN1 may be entirely formed in a portion overlapping the light-emitting area EA and the non-light-emitting area NLA, and may assist in applying a low-potential voltage to the cathode electrode CE.

The first bank layer BN1 may include a conductive metal having etching resistance. In an embodiment, the first bank layer BN1 may include titanium (Ti).

The second bank layer BN2 may be disposed in contact with the first bank layer BN1 in a portion overlapping the light-emitting area EA. A plurality of second bank layers BN2 may be formed and may be spaced apart from each other in the first direction DR1. In other words, the plurality of second bank layers BN2 may be disposed in the portions overlapping the first to third light-emitting areas EA1, EA2, and EA3, respectively, and each second bank layer BN2 may be formed in an island-shaped conductive pattern.

The second bank layer BN2 disposed in the portion overlapping the first light-emitting area EA1, the second bank layer BN2 disposed in the portion overlapping the second light-emitting area EA2, and the second bank layer BN2 disposed in the portion overlapping the third light-emitting area EA3 may be electrically connected by the first bank layer BN1.

The second bank layer BN2 may include a metal with relatively high electrical conductivity. In an embodiment, the second bank layer BN2 may include aluminum (Al).

The third bank layer BN3 may be disposed in contact with the second bank layer BN2. A plurality of third bank layers BN3 may be formed and may be spaced apart from each other in the first direction DR1. In other words, the plurality of third bank layers BN3 may be disposed in the portions overlapping the first to third light-emitting areas EA1, EA2, and EA3, respectively, and each third bank layer BN3 may be formed in an island-shaped conductive pattern.

In an embodiment, the third bank layer BN3 disposed in the portion overlapping the first light-emitting area EA1, the third bank layer BN3 disposed in the portion overlapping the second light-emitting area EA2, and the third bank layer BN3 disposed in the portion overlapping the third light-emitting area EA3 may be electrically connected through the second bank layer BN2 and the first bank layer BN1.

The third bank layer BN3 may include a conductive metal having etching resistance. In an embodiment, the third bank layer BN3 may include titanium (Ti).

In some embodiments, a second bank layer BN2 disposed next (adjacent) to the via hole VIH may include a first side surface 2c facing the via hole VIH and a second side surface 2d opposite to the first side surface 2c. In addition, a second bank layer BN2 disposed non-neighboring (non-adjacent) to the via hole VIH may include a second side surface 2d in a direction facing the non-light-emitting area NLA. In other words, the second bank layer BN2 disposed next (adjacent) to the via hole VIH may have a left-right asymmetrical structure, and the second bank layer BN2 disposed non-neighboring (non-adjacent) to the via hole VIH may have a left-right symmetrical structure. Details will be described later.

In an embodiment, the third bank layer BN3 may include a tip that protrudes further in the first direction DR1 than the first side surface 2c and/or the second side surface 2d of the second bank layer BN2. Accordingly, the second bank layer BN2 and the tip of the third bank layer BN3 may form an undercut, and the bank structure BN may have an overhang structure. As used herein, an “overhang structure” refers to a structural configuration in which an upper layer (e.g., the third bank layer BN3) extends laterally beyond the side surface(s) of a lower layer (e.g., the second bank layer BN2), thereby forming a protruding portion or ledge when viewed in cross-section.

The display device 10 in an embodiment may include a first light-emitting element ED1, a second light-emitting element ED2, and a third light-emitting element ED3 spaced apart from each other without a separate fine metal mask in the fabricating process, as the third bank layer BN3 includes the tip. The fabricating process will be described later.

The element insulating layer DIL may include a first element insulating layer DIL1 and a second element insulating layer DIL2.

The first element insulating layer DIL1 may be disposed on the third bank layer BN3. The first element insulating layer DIL1 may cover the third bank layer BN3 and may overlap the tip of the third bank layer BN3 in the third direction DR3.

The first element insulating layer DIL1 may separate and insulate the bank structure BN and the anode electrode AE from each other so that the bank structure BN and the anode electrode AE are not in contact with each other.

The first element insulating layer DIL1 may include an inorganic insulating material. In an embodiment, the first element insulating layer DIL1 may include at least one of silicon nitride, silicon oxide, and silicon oxynitride.

The second element insulating layer DIL2 may be disposed on the first element insulating layer DIL1. The second element insulating layer DIL2 may define the light-emitting opening OP1 and expose the anode electrode AE in a portion overlapping the light-emitting opening OP1. In other words, the second element insulating layer DIL2 may be disposed to surround the light-emitting opening OP1 and cover an edge of the anode electrode AE.

The second element insulating layer DIL2 may include an inorganic insulating material. In an embodiment, the second element insulating layer DIL2 may include at least one of silicon nitride, silicon oxide, and silicon oxynitride.

The light-emitting element ED may be disposed on the bank structure BN. The light-emitting element ED may overlap the bank structure BN and the element insulating layer DIL in the third direction DR3.

The display device 10 in an embodiment may be applied to a high-resolution electronic device. Therefore, a plurality of light-emitting elements ED included in the display device 10 may be desired to be disposed within a narrow area while securing an appropriate separation distance. Accordingly, in the display device 10 in an embodiment, the plurality of light-emitting elements may be efficiently disposed within the narrow area by forming the light-emitting element ED to be disposed on the bank structure BN.

The light-emitting element ED may include a first light-emitting element ED1 disposed in the first light-emitting area EA1, a second light-emitting element ED2 disposed in the second light-emitting area EA2, and a third light-emitting element ED3 disposed in the third light-emitting area EA3. The first light-emitting element ED1, the second light-emitting element ED2, and the third light-emitting element ED3 may be spaced apart from each other.

The first light-emitting element ED1 may include an anode electrode AE, a first light-emitting layer EL1, and a cathode electrode CE, the second light-emitting element ED2 may include an anode electrode AE, a second light-emitting layer EL2, and a cathode electrode CE, and the third light-emitting element ED3 may include an anode electrode AE, a third light-emitting layer EL3, and a cathode electrode CE.

The first light-emitting element ED1, the second light-emitting element ED2, and the third light-emitting element ED3 may emit light of different colors. In an embodiment, the first light-emitting element ED1 may emit red light, the second light-emitting element ED2 may emit green light, and the third light-emitting element ED3 may emit blue light. The colors emitted by the first light-emitting element ED1, the second light-emitting element ED2, and the third light-emitting element ED3 may be determined by the first light-emitting layer EL1, the second light-emitting layer EL2, and the third light-emitting layer EL3.

The anode electrode AE may be disposed on the first element insulating layer DIL1. The anode electrode AE may be disposed in a portion overlapping the light-emitting area EA and/or the light-emitting opening OP1.

The anode electrode AE may have a stacked film structure in which a material layer having a relatively high work function, such as indium tin oxide (“ITO”), indium zinc oxide (“IZO”), zinc oxide (ZnO), or indium oxide (In₂O₃) and a reflective material layer such as silver (Ag), magnesium (Mg), aluminum (Al), platinum (Pt), lead (Pd), palladium (Pd), gold (Au), nickel (Ni), neodymium (Nd), iridium (Ir), chromium (Cr), lithium (Li), or any combinations thereof are stacked. In an embodiment, the anode electrode AE may have a multilayer structure of ITO/Mg, ITO/MgF, ITO/Ag, and ITO/Ag/ITO, but is not limited thereto.

The first to third light-emitting layers EL1, EL2, and EL3 may be disposed on the anode electrode AE. The first to third light-emitting layers EL1, EL2, and EL3 may be disposed in portions overlapping the light-emitting area EA and the non-light-emitting area NLA. The first to third light-emitting layers EL1, EL2, and EL3 may overlap the bank structure BN and the element insulating layer DIL in the third direction DR3.

The first to third light-emitting layers EL1, EL2, and EL3 may contact the anode electrode AE in a portion overlapping the light-emitting opening OP1 and may cover an entirety of the second element insulating layer DIL2 in the portion overlapping the non-light-emitting area NLA.

In some embodiments, the first to third light-emitting layers EL1, EL2, and EL3 may contact and cover a portion of the third bank layer BN3 and the first element insulating layer DIL1.

The first light-emitting layer EL1 may be disposed in a portion overlapping the first light-emitting area EA1, the second light-emitting layer EL2 may be disposed in a portion overlapping the second light-emitting area EA2, and the third light-emitting layer EL3 may be disposed in a portion overlapping the third light-emitting area EA3. The first light-emitting layer EL1, the second light-emitting layer EL2, and the third light-emitting layer EL3 may be spaced apart from each other in the portion overlapping the non-light-emitting area NLA.

The first to third light-emitting layers EL1, EL2, and EL3 may be organic light-emitting layers including organic materials. The first to third light-emitting layers EL1, EL2, and EL3 may include any commonly used materials.

The first light-emitting layer EL1, the second light-emitting layer EL2, and the third light-emitting layer EL3 may emit light of different colors. In an embodiment, the first light-emitting layer EL1 may emit red light, the second light-emitting layer EL2 may emit green light, and the third light-emitting layer EL3 may emit blue light, but the disclosure is not limited thereto.

The cathode electrode CE may be disposed on the first to third light-emitting layers EL1, EL2, and EL3. The cathode electrode CE may be disposed in the portions overlapping the light-emitting area EA and the non-light-emitting area NLA. The cathode electrode CE may cover an entirety of the first to third light-emitting layers EL1, EL2, and EL3.

The cathode electrode CE may contact the bank structure BN, and thus may be electrically connected to the bank structure BN. Specifically, the cathode electrode CE may contact the tip of the third bank layer BN3.

In some embodiments, the cathode electrode CE may also contact the side surface of the second bank layer BN2. However, depending on the process conditions, the cathode electrode CE may not contact the second bank layer BN2 and may only contact the tip of the third bank layer BN3.

The cathode electrode CE includes a metal with relatively high electrical conductivity and a transparent conductive oxide, so that the light generated in the first to third light-emitting layers EL1, EL2, and EL3 may be emitted. In an embodiment, the cathode electrode CE may include a material layer having a relatively low work function, such as Li, Ca, LiF/Ca, LiF/Al, Al, Mg, Ag, Pt, Pd, Ni, Au, Nd, Ir, Cr, BaF, Ba, or a compound or combination thereof (e.g., a combination of Ag and Mg, etc.).

In an embodiment, the cathode electrode CE disposed in a portion overlapping the first light-emitting area EA1, the cathode electrode CE disposed in a portion overlapping the second light-emitting area EA2, and the cathode electrode CE disposed in a portion overlapping the third light-emitting area EA3 may be spaced apart from each other. The cathode electrodes CE disposed spaced apart from each other in the first to third light-emitting areas EA1, EA2, and EA3 may be electrically connected through the bank structure BN. Specifically, the cathode electrodes CE disposed to be spaced apart from each other in the first to third light-emitting areas EA1, EA2, and EA3 may contact third bank layers BN3 disposed to be spaced apart from each other in the first to third light-emitting areas EA1, EA2, and EA3, and may be electrically connected to each other through the second bank layer BN2 and the first bank layer BN1 that are electrically connected to the third bank layer BN3.

In some embodiments, the cathode electrode CE may be formed in a structure in which a plurality of conductive layers are stacked. When the cathode electrode CE includes a plurality of conductive layers, the cathode electrode CE may have a structure in which a transparent conductive oxide is stacked on a metal layer having relatively high electrical conductivity.

The element inorganic layer IO may be disposed on the light-emitting element ED. The element inorganic layer IO may completely cover the light-emitting element ED and prevent oxygen or moisture from permeating into the light-emitting element ED.

The element inorganic layer IO may include an inorganic insulating material. In an embodiment, the element inorganic layer IO may include at least one of silicon nitride, silicon oxide, and silicon oxynitride.

The element inorganic layer IO may include a first element inorganic layer IO1, a second element inorganic layer IO2, and a third element inorganic layer IO3. The first element inorganic layer IO1 may be disposed on the first light-emitting element ED1 in the first light-emitting area EA1, the second element inorganic layer IO2 may be disposed on the second light-emitting element ED2 in the second light-emitting area EA2, and the third element inorganic layer IO3 may be disposed on the third light-emitting element ED3 in the third light-emitting area EA3. The first element inorganic layer IO1, the second element inorganic layer IO2, and the third element inorganic layer IO3 may be spaced apart from each other in a portion overlapping the non-light-emitting area NLA.

In the drawing, the first element inorganic layer IO1, the second element inorganic layer IO2, and the third element inorganic layer IO3 appear to be formed in the same layer, but in the process of fabricating the display device 10, the first element inorganic layer IO1 may be formed after the first light-emitting element ED1 is formed, the second element inorganic layer IO2 may be formed after the second light-emitting element ED2 is formed, and the third element inorganic layer IO3 may be formed after the third light-emitting element ED3 is formed. The fabricating process will be described later.

The thin film encapsulation layer TFEL may be disposed on the display element layer EML. The thin film encapsulation layer TFEL may include an organic encapsulation layer TFE1 and an inorganic encapsulation layer TFE3.

The organic encapsulation layer TFE1 in an embodiment may be disposed on the element inorganic layer IO. In an embodiment, the organic encapsulation layer TFE1 may be entirely in contact with and cover the first element inorganic layer IO1, the second element inorganic layer IO2, and the third element inorganic layer IO3.

The organic encapsulation layer TFE1 may planarize the step formed according to a profile of the lower structure. The organic encapsulation layer TFE1 may fill a spaced portion between the cathode electrode CE and the first bank layer BN1 in the portion overlapping the non-light-emitting area NLA.

The organic encapsulation layer TFE1 may include a polymer-based material. In an embodiment, the organic encapsulation layer TFE1 may include an acrylic resin, a silicone resin, an epoxy resin, a silicone acrylic resin, polyimide, and polyethylene.

The inorganic encapsulation layer TFE3 may be disposed on the organic encapsulation layer TFE1. The inorganic encapsulation layer TFE3 may protect the lower structure from permeation of moisture and oxygen. Depending on the embodiment, the inorganic encapsulation layer TFE3 may also be omitted.

The inorganic encapsulation layer TFE3 may include an inorganic insulating material. In an embodiment, the inorganic encapsulation layer TFE3 may include at least one of silicon nitride, silicon oxide, and silicon oxynitride.

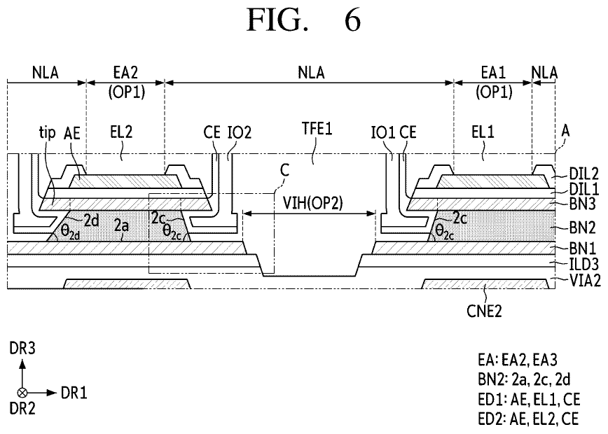

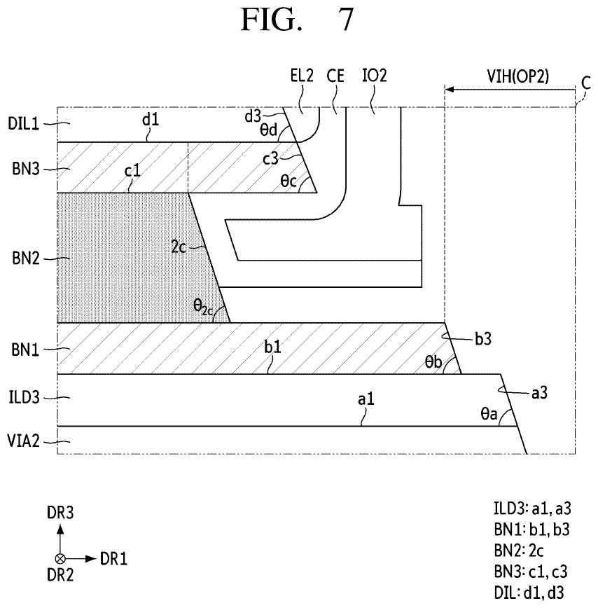

FIG. 6 is an enlarged cross-sectional view of area ‘A’ in FIG. 5 and FIG. 7 is an enlarged cross-sectional view of area ‘C’ in FIG. 6.

Referring to FIGS. 6 and 7 in addition to FIGS. 1 to 5, in an embodiment, the via hole VIH may be defined to penetrate through the third insulating layer ILD3 and the first bank layer BN1 in a portion overlapping the non-light-emitting area NLA. In an embodiment, the first bank layer BN1, the second bank layer BN2, and the third bank layer BN3 may be disposed to surround the via hole VIH.

The via hole VIH may define a non-light-emitting opening OP2. In cross-sectional view, the non-light-emitting opening OP2 may not overlap the light-emitting opening OP1 and/or the light-emitting area EA.

The via hole VIH may function as an outgas path for the organic material included in the display device 10. The second via layer VIA2 may be exposed in a portion overlapping the via hole VIH and/or the non-light-emitting opening OP2. The second via layer VIA2 exposed in the portion overlapping the via hole VIH and/or the non-light-emitting opening OP2 may contact the organic encapsulation layer TFE1.

In the process of fabricating the display device 10, the via hole VIH may be defined by removing a portion of the third insulating layer ILD3 and the first bank layer BN1 through a dry etching process. The dry etching process may be performed as the same process as the process of removing the first element insulating layer DIL1 and the third bank layer BN3. Accordingly, one surface of each of the third insulating layer ILD3, the first bank layer BN1, the third bank layer BN3, and the first element insulating layer DIL1 facing the via hole VIH and/or the non-light-emitting opening OP2 may have a similar shape. In an embodiment, one surface of each of the third insulating layer ILD3, the first bank layer BN1, the third bank layer BN3, and the first element insulating layer DIL1 facing the via hole VIH and/or the non-light-emitting opening OP2 may have a regular tapered or trapezoidal shape.

Specifically, in an embodiment, the third insulating layer ILD3 may include a first surface a1 facing the second via layer VIA2 and a side surface a3 facing the via hole VIH and/or the non-light-emitting opening OP2. A first inclined angle θa defined by the first surface a1 and the side surface a3 of the third insulating layer ILD3 may be an acute angle. In an embodiment, the first inclined angle θa may have a value of 60 degrees or more and 80 degrees or less.

In addition, the first bank layer BN1 may include a first surface b1 facing the third insulating layer ILD3 and a side surface b3 facing the via hole VIH and/or the non-light-emitting opening OP2. A second inclined angle θb defined by the first surface b1 and the side surface b3 of the first bank layer BN1 may be an acute angle. In an embodiment, the second inclined angle θb may have a value of 60 degrees or more and 80 degrees or less.

In addition, the third bank layer BN3 may include a first surface c1 facing the second bank layer BN2 and a side surface c3 facing the via hole VIH and/or the non-light-emitting opening OP2. A third inclined angle θc defined by the first surface c1 and the side surface c3 of the third bank layer BN3 may be an acute angle. In an embodiment, the third inclined angle θc may have a value of 60 degrees or more and 80 degrees or less.

In addition, the first element insulating layer DIL1 may include a first surface d1 facing the third bank layer BN3 and a side surface d3 facing the via hole VIH and/or the non-light-emitting opening OP2. A fourth inclined angle θd defined by the first surface d1 and the side surface d3 of the first element insulating layer DIL1 may be an acute angle. In an embodiment, the fourth inclined angle θd may have a value of 60 degrees or more and 80 degrees or less.

In the process of fabricating the display device 10, the second bank layer BN2 may be formed by a dry etching process and a wet etching process. Accordingly, the second bank layer BN2 may have a different shape from the third insulating layer ILD3, the first bank layer BN1, the third bank layer BN3, and the first element insulating layer DIL1.

In some embodiments, the first side surface 2c of the second bank layer BN2 disposed next (adjacent) to the via hole VIH and the second side surface 2d opposite to the first side surface 2c may have different taper angles. In other words, the second side surface 2d disposed next (adjacent) to the via hole VIH may have a more inclined cross-section than the first side surface 2c. In an embodiment, a first inclined angle θ2c defined by the first surface 2a and the first side surface 2c may be greater than a second inclined angle θ2d defined by the first surface 2a and the second side surface 2d. This may be caused by the first side surface 2c and the second side surface 2d of the second bank layer BN2 being formed by performing different processes. The fabricating process will be described later.

In an embodiment, the first light-emitting element ED1 and the first element inorganic layer IO1 disposed in a portion overlapping the first light-emitting area EA1 may be spaced apart from the second light-emitting element ED2 and the second element inorganic layer IO2 disposed in a portion overlapping the second light-emitting area EA2 with the via hole VIH and/or the non-light-emitting opening OP2.

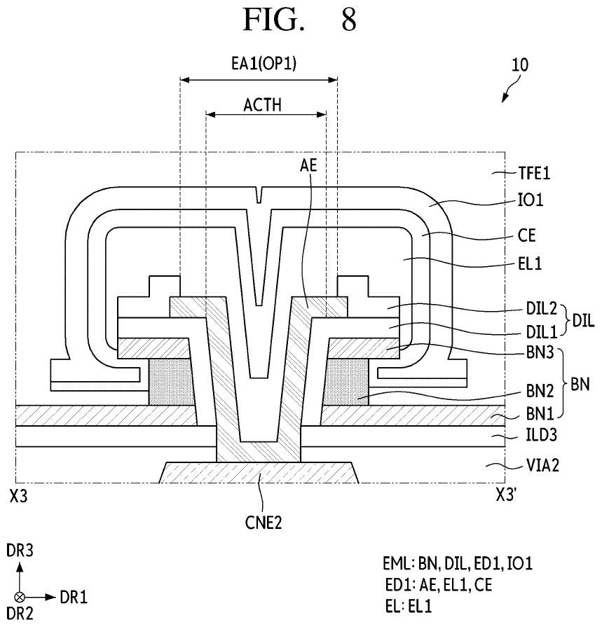

FIG. 8 is a cross-sectional view illustrating an embodiment of a display element layer taken along line X3-X3′ of FIG. 4. FIG. 8 illustrates a cross-sectional structure of the display element layer EML in a portion overlapping the anode contact hole ACTH.

Referring to FIG. 8 in addition to FIGS. 1 to 7, the anode contact hole ACTH included in the display device 10 may overlap the light-emitting area EA.

In an embodiment, the anode contact hole ACTH may be defined in a portion overlapping the light-emitting opening OP1. The anode contact hole ACTH may be formed to penetrate through the bank structure BN and the third insulating layer ILD3, and the second connection electrode CNE2 overlapping the anode contact hole ACTH may be exposed.

The first bank layer BN1, the second bank layer BN2, and the third bank layer BN3 may be disposed to surround the anode contact hole ACTH. A side surface of the first bank layer BN1, a side surface of the second bank layer BN2, and a side surface of the third bank layer BN3 facing the anode contact hole ACTH may be disposed on the same line.

The anode electrode AE may be spaced apart from the first bank layer BN1, the second bank layer BN2, and the third bank layer BN3 with the first element insulating layer DIL1. In an embodiment, the anode electrode AE may cover along the step formed by the first element insulating layer DIL1. Accordingly, the anode electrode AE may include a step in a portion overlapping the anode contact hole ACTH.

In the portion overlapping the anode contact hole ACTH, the anode electrode AE and the second connection electrode CNE2 may contact each other and electrically connected.

The light-emitting layer EL may cover along the step formed by the anode electrode AE in the portion overlapping the anode contact hole ACTH. Accordingly, in an embodiment, the light-emitting layer EL may include a step in the portion overlapping the anode contact hole ACTH.

The cathode electrode CE may cover along the step formed by the anode electrode AE in the portion overlapping the anode contact hole ACTH. Accordingly, in an embodiment, the cathode electrode CE may include a step in the portion overlapping the anode contact hole ACTH.

The first element inorganic layer IO1 may cover along the step formed by the anode electrode AE in the portion overlapping the anode contact hole ACTH. Accordingly, in an embodiment, the first element inorganic layer IO1 may include a step in the portion overlapping the anode contact hole ACTH. However, the specification is not limited thereto, and the first element inorganic layer IO1 may not include the step in the portion overlapping the anode contact hole ACTH. Other redundant descriptions will be omitted.

For convenience of explanation, the anode contact hole ACTH disposed in the portion overlapping the first light-emitting area EA1 is illustrated and then described, but the anode contact holes ACTH disposed in the portions overlapping the second light-emitting area EA2 and the third light-emitting area EA3 may have a structure and characteristics similar to the anode contact hole ACTH disposed in the portion overlapping the first light-emitting area EA1.

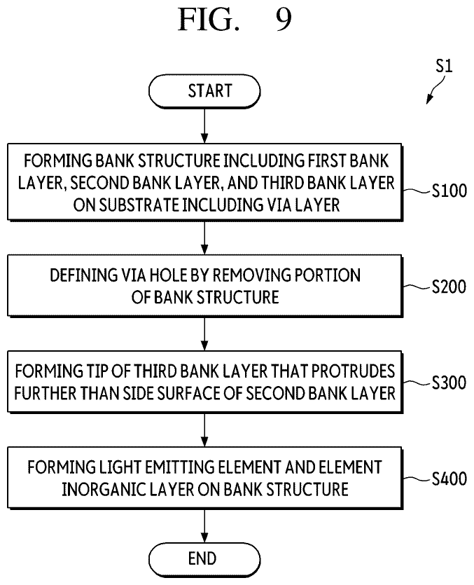

FIG. 9 is a flowchart illustrating a fabricating process of forming a display element layer and a via hole in FIG. 5.

Referring to FIG. 9 in addition to FIGS. 1 to 8, a method S1 for fabricating the display element layer and the via hole defined in the display device 10 in an embodiment may include an operation (S100) of forming a bank structure including a first bank layer, a second bank layer, and a third bank layer on a substrate including a via layer, an operation (S200) of defining a via hole by removing a portion of the bank structure, an operation (S300) of forming a tip of the third bank layer that protrudes further than a side surface of the second bank layer, and an operation (S400) of forming a light-emitting element and an element inorganic layer on the bank structure.

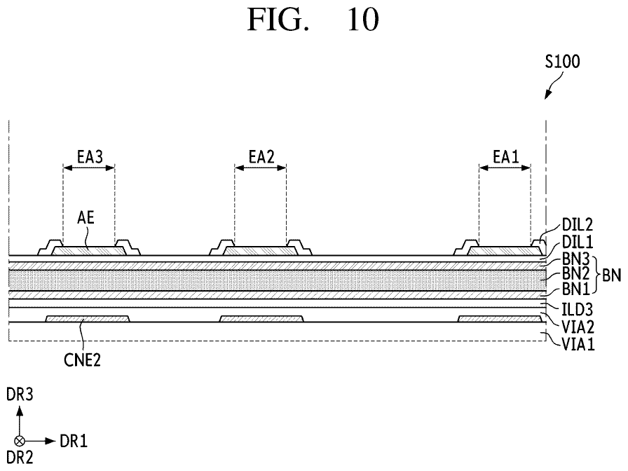

FIG. 10 is a cross-sectional view for describing operation S100 of FIG. 9.

An operation (S100) of forming a bank structure including a first bank layer, a second bank layer, and a third bank layer on a substrate including a via layer will be described with reference to FIG. 10.

First, a plurality of second connection electrodes CNE2 are formed on a first via layer VIA1, and a second via layer VIA2, a third insulating layer ILD3, a bank structure BN, and a first element insulating layer DIL1 are entirely formed.

In the process, the bank structure BN may include a first bank layer BN1, a second bank layer BN2, and a third bank layer BN3 that are sequentially stacked.

In the process, the second bank layer BN2 and the third bank layer BN3 may include different materials from each other. In an embodiment, the third bank layer BN3 may include a material having higher etching resistance than the second bank layer BN2. The redundant descriptions will be omitted.

Although not illustrated in the drawings, a thin film transistor layer TFTL including the first via layer VIA1 and the second via layer VIA2 may be disposed on the substrate SUB, and a detailed structure of the thin film transistor layer TFTL is the same as that illustrated in FIG. 5.

Next, an anode electrode AE and a second element insulating layer DIL2 are formed on the first element insulating layer DIL1. In the process, a plurality of anode electrodes AE may be formed and may be disposed in portions overlapping the first light-emitting area EA1, the second light-emitting area EA2, and the third light-emitting area EA3.

In the process, the second element insulating layer DIL2 may be temporarily formed to cover an entirety of the plurality of anode electrodes AE and the first element insulating layer DIL1, and may then be formed into the shape currently illustrated through a subsequent patterning process.

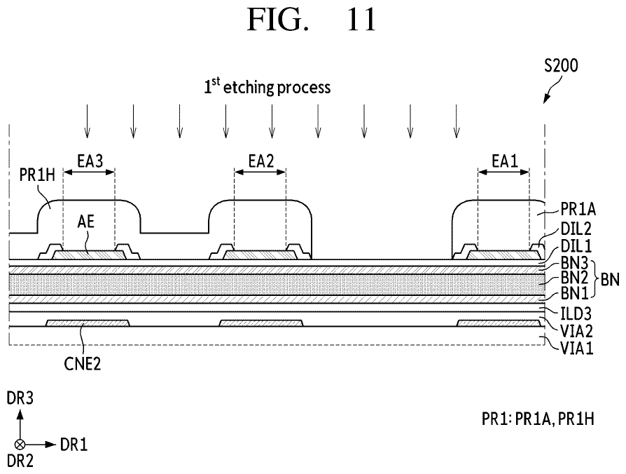

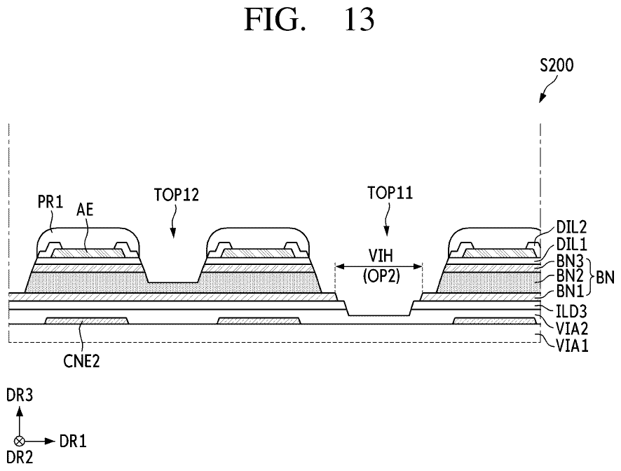

FIGS. 11 to 13 are cross-sectional views for describing operation S200 of FIG. 9.

A operation (S200) of defining a via hole by removing a portion of the bank structure will be described with reference to FIGS. 11 to 13 in addition to FIGS. 1 to 10.

First, a photoresist PR1 is formed on the anode electrode AE and the second element insulating layer DIL2, and a first etching process is performed. In the process, the photoresist PR1 may cover an entirety of the anode electrode AE and the second element insulating layer DIL2.

In the process, the photoresist PR1 may include a halftone mask PR1H and a photomask PR1A. The halftone mask PR1H and the photomask PR1A may be spaced apart, and the first element insulating layer DIL1 may be exposed in a portion where the halftone mask PR1H and the photomask PR1A are not formed.

In the process, the first etching process may be performed as a dry etching process. In an embodiment, the dry etching process may be performed through a reactive ion etching (“RIE”) process using reactive gases such as CHF₃, CH₃F, CH₂F₂, CHF₆, CF₄, C₂F₆, and C₃F₆, and sputtering gases such as Ar, and O₂/Ar, for example. In this case, an inductively coupled plasma (“ICP”) source or a capacitively coupled plasma (“CCP”) source may be used as a plasma source.

Through the process, the first element insulating layer DIL1, the third bank layer BN3, and the second bank layer BN2 that do not overlap the photoresist PR1 may be removed at once. Accordingly, a first temporary opening TOP11 may be defined in a portion that does not overlap the photoresist PR1, and the first bank layer BN1 may be exposed in a portion overlapping the first temporary opening TOP11.

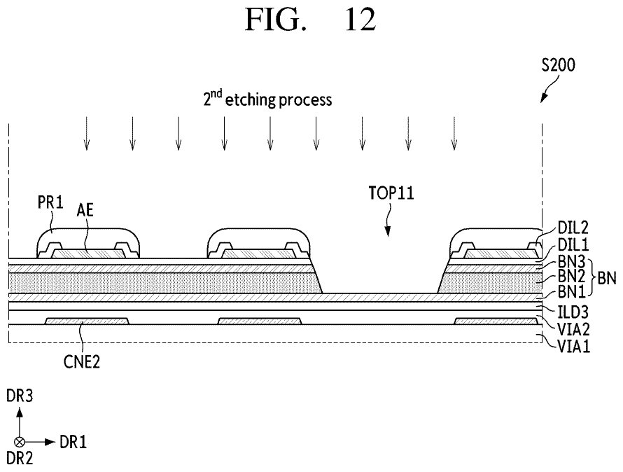

Through the process, a portion of an upper portion of the halftone mask PR1H and the photomask PR1A may be removed, whereby the halftone mask PR1H and the photomask PR1A may remain in the form of the photoresist PR1 as illustrated in FIG. 12.

In the process, the first element insulating layer DIL1 that does not overlap the first temporary opening TOP11 and the photoresist PR1 may be exposed.

Next, a second etching process is performed using the photoresist PR1 as it is. In the process, the second etching process may be performed as a dry etching process. In an embodiment, the second etching process may include the same process as the first etching process, for example.

Through the process, a portion of the first bank layer BN1 and a portion of the third insulating layer ILD3 overlapping the first temporary opening TOP11 may be removed. Depending on the embodiment, a portion of the second via layer VIA2 may also be removed in the process.

In this way, a via hole VIH may be defined. The via hole VIH may define a non-light-emitting opening OP2, and the second via layer VIA2 may be exposed in a portion overlapping the via hole VIH and/or the non-light-emitting opening OP2. The redundant descriptions will be omitted.

In the process, as the third insulating layer ILD3, the first bank layer BN1, the third bank layer BN3, and the first element insulating layer DIL1 overlapping the first temporary opening TOP11 are formed by performing the same process, one surface of the third insulating layer ILD3, the first bank layer BN1, the third bank layer BN3, and the first element insulating layer DIL1 facing the via hole VIH may have a similar taper angle. The redundant descriptions will be omitted.

Through the process, a second temporary opening TOP12 may be defined in a portion that does not overlap the first temporary opening TOP11 and the photoresist PR1. The second temporary opening TOP12 may be defined by removing a portion of the first element insulating layer DIL1, the third bank layer BN3, and the second bank layer BN2 disposed the portion that does not overlap the first temporary opening TOP11 and the photoresist PR1. The process of forming the second temporary opening TOP12 may be performed simultaneously with the process of defining the via hole VIH.

In the process, the second bank layer BN2 overlapping the second temporary opening TOP12 may not be entirely removed and may partially remain. Accordingly, the second bank layer BN2 may be exposed in a portion overlapping the second temporary opening TOP12.

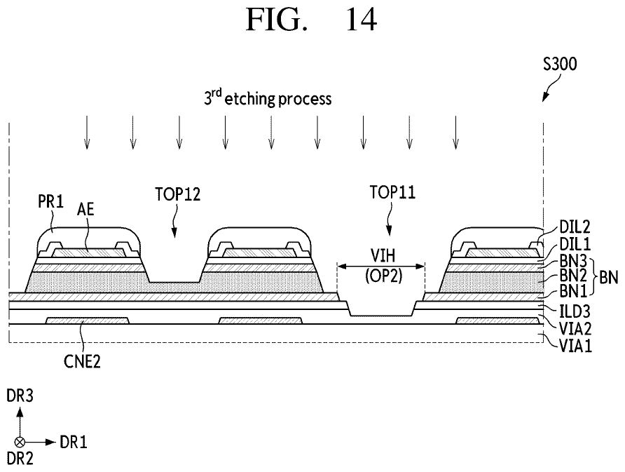

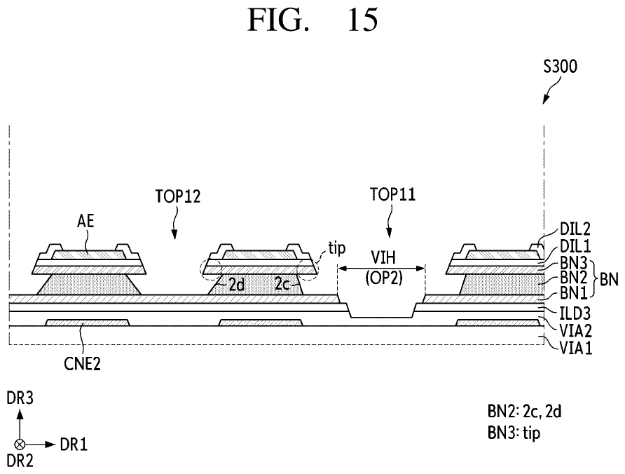

FIGS. 14 and 15 are cross-sectional views for describing operation S300 of FIG. 9.

An operation (S300) of forming a tip of the third bank layer that protrudes further than a side surface of the second bank layer will be described with reference to FIGS. 14 and 15 in addition to FIGS. 1 to 13.

First, a third etching process is performed using the photoresist PR1 as it is. In an embodiment, the third etching process may be performed as a wet etching process. In the process, the second bank layer BN2 that does not overlap the photoresist PR1 may be completely removed.

In an embodiment, the wet etching process may be performed using liquid chemical solutions such as diluted hydrofluoric acid solution, nitric acid solution, tetramethylammonium hydroxide solution, potassium hydroxide solution, etc.

In the process, the second bank layer BN2 may have a relatively high etching rate for the etchant used in the wet etching process. Accordingly, the first side surface 2c and the second side surface 2d of the second bank layer BN2 may be more depressed in the first direction DR1 than the third bank layer BN3.

In the process, titanium (Ti) included in the third bank layer BN3 and the first bank layer BN1 may have etching resistance against a wet etchant. Accordingly, the third bank layer BN3 and the first bank layer BN1 may not react to the etching solution of the third etching process.

In the process, the first side surface 2c of the second bank layer BN2 facing the first temporary opening TOP11 and/or the via hole VIH and the second side surface 2d of the second bank layer BN2 facing the second temporary opening TOP12 may have different slopes.

Specifically, in the process, one surface of the second bank layer BN2 facing the first temporary opening TOP11 and/or the via hole VIH may be defined by performing the third etching process after being isotropically removed entirely by the first etching process. Unlike this, one surface of the second bank layer BN2 facing the second temporary opening TOP12 may be formed by performing the third etching process after a portion is removed and a portion remains through the second etching process. That is, when performing the third etching process, one surface of the second bank layer BN2 facing the first temporary opening TOP11 and/or the via hole VIH may be entirely removed at the same etching rate, and in one surface of the second bank layer BN2 facing the second temporary opening TOP12, the already removed portion of the second bank layer BN2 may be removed at a faster rate than the remaining portion of the second bank layer BN2.

Therefore, the second side surface 2d of the second bank layer BN2 facing the second temporary opening TOP12 may have a more inclined surface than the first side surface 2c facing the first temporary opening TOP11 and/or the via hole VIH.

In this way, the bank structure BN including the tip of the third bank layer BN3 may be formed and the via hole VIH may be defined. Although not illustrated in the drawing, the photoresist PR1 may be removed by performing an ashing process.

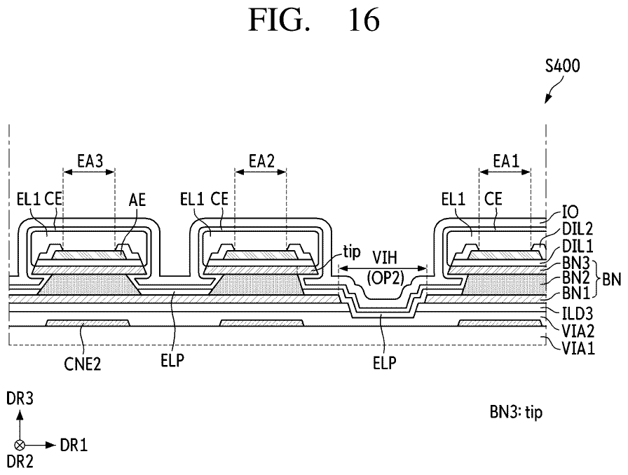

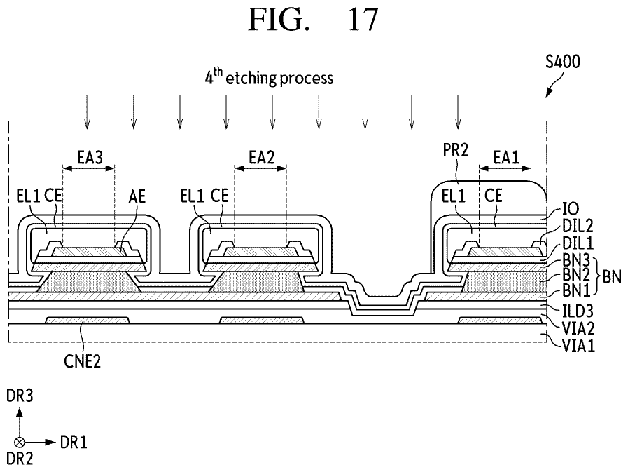

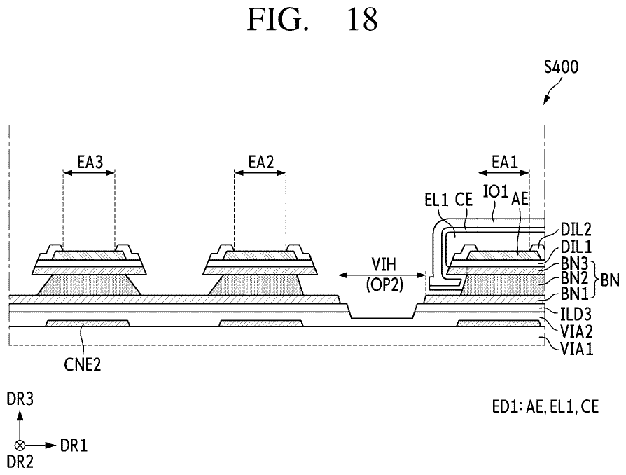

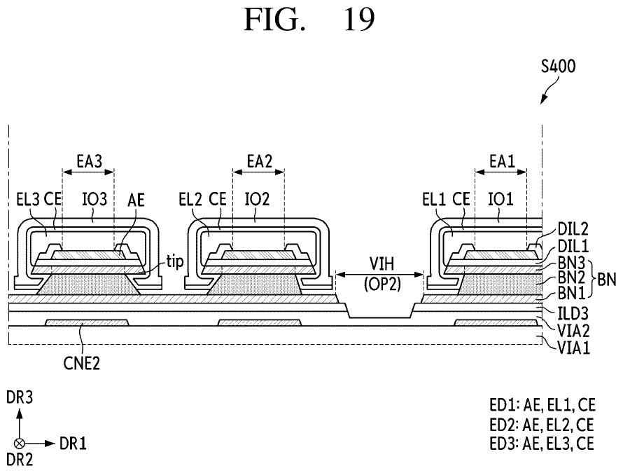

FIGS. 16 to 19 are cross-sectional views for describing operation S400 of FIG. 9.

An operation (S400) of forming a light-emitting element and an element inorganic layer on the bank structure will be described with reference to FIGS. 16 to 19 in addition to FIGS. 1 to 15.

First, a first light-emitting element ED1 is formed by depositing a first light-emitting layer EL1 and a cathode electrode CE on the anode electrode AE.

In the process, the process of forming the first light-emitting layer EL1 may be performed through a thermal deposition process. The process of forming the first light-emitting layer EL1 may be performed through entire surface deposition without a separate fine metal mask.

Accordingly, in the process, the material forming the first light-emitting layer EL1 may be formed not only on the anode electrode AE overlapping the first light-emitting area EA1, but may also be disposed on the anode electrodes AE disposed in portions overlapping the second light-emitting area EA2 and the third light-emitting area EA3. The first light-emitting layers EL1 disposed in portions overlapping the first to third light-emitting areas EA1, EA2, and EA3 may be spaced apart from each other.

In addition, the material forming the first light-emitting layer EL1 may also be formed on the first bank layer BN1 and the via hole VIH. The material forming the first light-emitting layer EL1 disposed on the anode electrode AE, the material forming the first light-emitting layer EL1 disposed on the first bank layer BN1, and the material forming the first light-emitting layer EL1 disposed in the portion overlapping the via hole VIH may be spaced apart from each other. In an embodiment, the material forming the first light-emitting layer EL1 disposed on the first bank layer BN1 may be referred to as an organic pattern ELP.

In the process, the process of forming the cathode electrode CE may be performed through a thermal deposition process or a sputtering process. The process of forming the cathode electrode CE may have a higher step coverage than the process of forming the first light-emitting layer EL1. Therefore, the cathode electrode CE may cover an entirety of the first light-emitting layer EL1.

In the process, the process of forming the cathode electrode CE may be performed through entire surface deposition without a separate fine metal mask. Accordingly, the material forming the cathode electrode CE may be formed not only on the first light-emitting layer EL1 overlapping the first light-emitting area EA1, but may also be disposed on the first light-emitting layer EL1 disposed in portions overlapping the second light-emitting area EA2 and the third light-emitting area EA3.

It is illustrated in the drawing that the cathode electrodes CE disposed in the portions overlapping the first to third light-emitting areas EA1, EA2, and EA3 are connected, but the specification is not limited thereto. Depending on the embodiment, the cathode electrodes CE disposed in the portions overlapping the first to third light-emitting areas EA1, EA2, and EA3 may also be spaced apart from each other.

In the process, the cathode electrode CE may be formed in contact with the tip of the third bank layer BN3.

Next, an element inorganic layer IO is formed on the cathode electrode CE. The element inorganic layer IO may cover an entirety of the cathode electrode CE with a uniform thickness along the profile of the lower structure.

In the process, the process of forming the element inorganic layer IO may be formed through a film forming process (e.g., a deposition process) that forms at least one of the above-mentioned inorganic materials.

Next, a photoresist PR2 is formed in the first light-emitting area EA1 and a portion overlapping a periphery of the first light-emitting area EA1, and a fourth etching process is performed using the photoresist PR2 as a mask. In an embodiment, in the fourth etching process, a dry etching process and a wet etching process may be alternately performed.

In the process, the material forming the first light-emitting layer EL1, the material forming the cathode electrode CE, and the material forming the element inorganic layer IO that do not overlap the photoresist PR2 may be completely removed. Accordingly, the anode electrode AE overlapping the second light-emitting area EA2 and the anode electrode AE overlapping the third light-emitting area EA3 may be exposed again, and the element inorganic layer IO may be formed in the form of a first element inorganic layer IO1.

In the process, the first element inorganic layer IO1 may be spaced apart from the first bank layer BN1 in the third direction DR3. This may be caused by the organic pattern ELP temporarily formed on the first bank layer BN1 being removed through the fourth etching process.

In this way, the first light-emitting element ED1 and the first element inorganic layer IO1 disposed in the portion overlapping the first light-emitting area EA1 may be formed.

Next, a second light-emitting layer EL2, a cathode electrode CE, and an element inorganic layer IO are formed on the anode electrode AE overlapping the second light-emitting area EA2 by repeating the above-described processes. Through the process, the second light-emitting element ED2 and the second element inorganic layer IO2 overlapping the second light-emitting area EA2 may be formed.

A third light-emitting layer EL3, a cathode electrode CE, and an element inorganic layer IO are formed on the anode electrode AE overlapping the third light-emitting area EA3 by repeating the above-described processes again. Through the process, the third light-emitting element ED3 and the third element inorganic layer IO3 overlapping the third light-emitting area EA3 may be formed.

In this way, the display element layer EML and the via hole VIH illustrated in FIG. 5 may be formed.

Referring back to FIGS. 5 to 19, in the display device 10 in an embodiment, the via hole VIH and the bank structure BN may be defined without a separate additional mask and/or a separate additional photoresist process by the halftone mask PR1H in the fabricating process. Therefore, the fabricating cost of the display device 10 in an embodiment may be reduced.

In addition, the display device 10 in an embodiment may have ease of fabrication by performing the first etching process, the second etching process, and the third etching process using the same photoresist PR1.

In addition, in the display device 10 in an embodiment, high-resolution pixels may be efficiently disposed by disposing the light-emitting element ED on the bank structure BN. Therefore, the display device 10 in an embodiment may provide a high-resolution product.

In addition, the display device 10 in an embodiment may emit outgas of the organic material by exposing the second via layer VIA2 including the organic material at the portion overlapping the via hole VIH, thereby solving the reliability problem caused by the organic outgas.

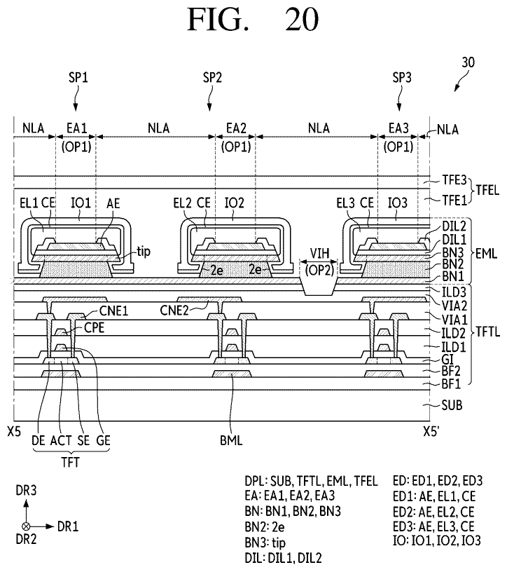

FIG. 20 is a cross-sectional view illustrating an embodiment of the display layer taken along line X5-X5′ of FIG. 4.

Referring to FIG. 20 in addition to FIGS. 1 to 19, a via hole VIH included in a display device 30 may be defined to penetrate through the first bank layer BN1, the third insulating layer ILD3, and the second via layer VIA2 in a portion overlapping the non-light-emitting area NLA. The via hole VIH defined in the display device 30 may define a non-light-emitting opening OP2. The non-light-emitting opening OP2 may not overlap the light-emitting opening OP1.

The via hole VIH defined in the display device 30 may be disposed between a plurality of bank structures BN. In an embodiment, the via hole VIH defined in the display device 30 may be disposed between the second bank layer BN2 and the third bank layer BN3 overlapping the second light-emitting area EA2 and the second bank layer BN2 and the third bank layer BN3 overlapping the third light-emitting area EA3. However, this is only an illustrative embodiment, and depending on the embodiments, the via hole VIH may also be defined between the second bank layer BN2 and the third bank layer BN3 overlapping the first light-emitting area EA1 and the second bank layer BN2 and the third bank layer BN3 overlapping the second light-emitting area EA2, and may also be disposed between the second bank layer BN2 and the third bank layer BN3 overlapping the first light-emitting area EA1 and the second bank layer BN2 and the third bank layer BN3 overlapping the third light-emitting area EA3.

The second bank layer BN2 included in the display device 30 may have a different shape from the second bank layer BN2 included in the display device 10. Hereinafter, the description of the common structure of the display device 10 and the display device 30 will be omitted and the differences thereof will be described.

The second bank layer BN2 included in the display device 30 may include a second side surface 2e facing the non-light-emitting area NLA. In the second bank layer BN2 included in the display device 30, one surface disposed in the direction toward the via hole VIH and one surface opposite thereto may have the same shape.

In a process of fabricating the display device 30, the via hole VIH may be defined after forming the bank structure BN. The fabricating process will be described later.

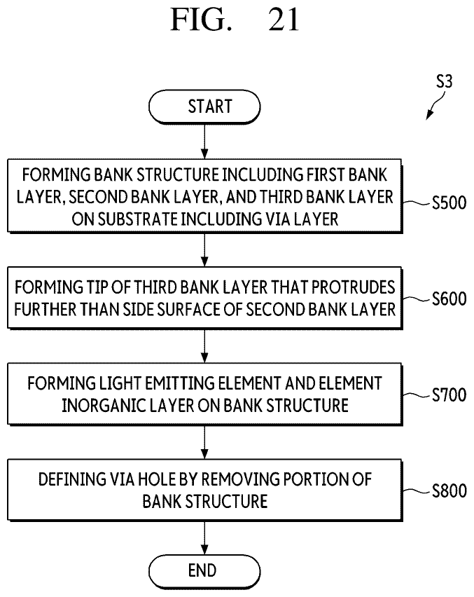

FIG. 21 is a flowchart illustrating a fabricating process of forming a display element layer and defining a via hole in FIG. 20.

Referring to FIG. 21, a method S3 for fabricating the display element layer and the via hole defined in the display device 30 in an embodiment may include an operation (S500) of forming a bank structure including a first bank layer, a second bank layer, and a third bank layer on a substrate including a via layer, an operation (S600) of forming a tip of the third bank layer that protrudes further than a side surface of the second bank layer, an operation (S700) of forming a light-emitting element and an element inorganic layer on the bank structure, and an operation (S800) of defining a via hole by removing a portion of the bank structure.

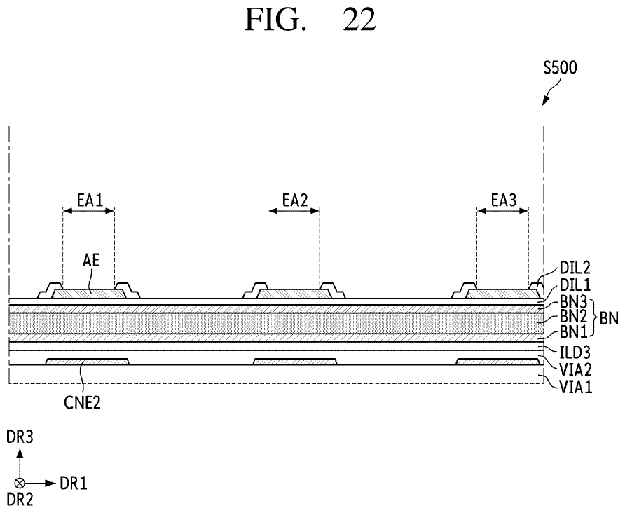

FIG. 22 is a cross-sectional view for describing operation S500 of FIG. 21.

An operation (S500) of forming a bank structure including a first bank layer, a second bank layer, and a third bank layer on a substrate including a via layer will be described with reference to FIG. 22 in addition to FIGS. 1 to 21.

In an embodiment, the operation (S500) of forming the bank structure including the first bank layer, the second bank layer, and the third bank layer on the substrate including the via layer may be same as the operation (S100) of forming the bank structure including the first bank layer, the second bank layer, and the third bank layer on the substrate including the via layer described with reference to FIG. 10. The redundant descriptions will be omitted.

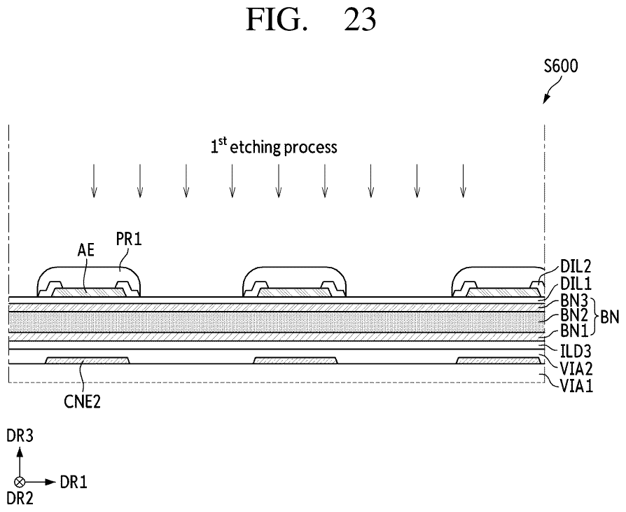

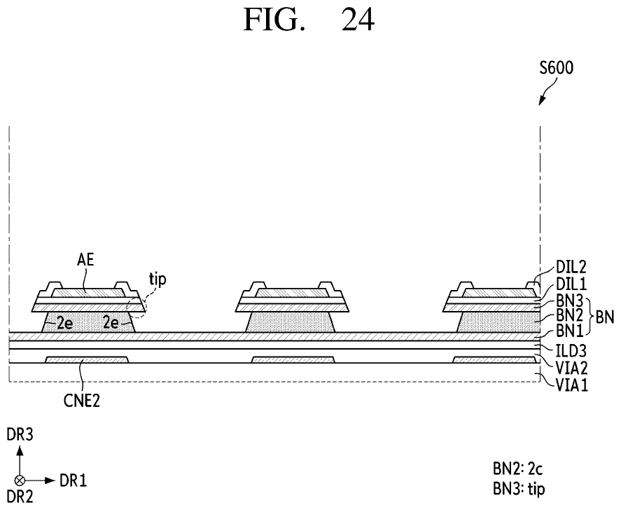

FIGS. 23 and 24 are cross-sectional views for describing operation S600 of FIG. 21.

An operation (S600) of forming a tip of the third bank layer that protrudes further than a side surface of the second bank layer will be described with reference to FIGS. 23 and 24 in addition to FIGS. 1 to 22.

First, a photoresist PR1 is formed on the anode electrode AE and the second element insulating layer DIL2, and a first etching process is performed. In the process, the photoresist PR1 may cover an entirety of the anode electrode AE and the second element insulating layer DIL2.

In the process, in the first etching process, a dry etching process and a wet etching process may be alternately performed.

First, the first element insulating layer DIL1, the third bank layer BN3, and the second bank layer BN2 that do not overlap the photoresist PR1 are removed at once by performing a dry etching process. Although not illustrated in the drawing, in the process, the first element insulating layer DIL1, the third bank layer BN3, and the second bank layer BN2 may have side surfaces disposed on the same line.

Secondly, a portion of the second bank layer BN2 that does not overlap the photoresist PR1 is removed by performing a wet etching process. In the process, the second bank layer BN2 may have a relatively high etching rate for the wet etchant. Accordingly, the side surface 2e of the second bank layer BN2 may be more depressed in the first direction DR1 than the third bank layer BN3. Accordingly, the third bank layer BN3 may have a tip that protrudes further in the first direction DR1 than the side surface 2e of the second bank layer BN2. In the process, the second bank layer BN2 may have a left-right symmetrical structure. The redundant descriptions will be omitted.

Although not illustrated in the drawing, the photoresist PR1 may be removed by performing an ashing process.

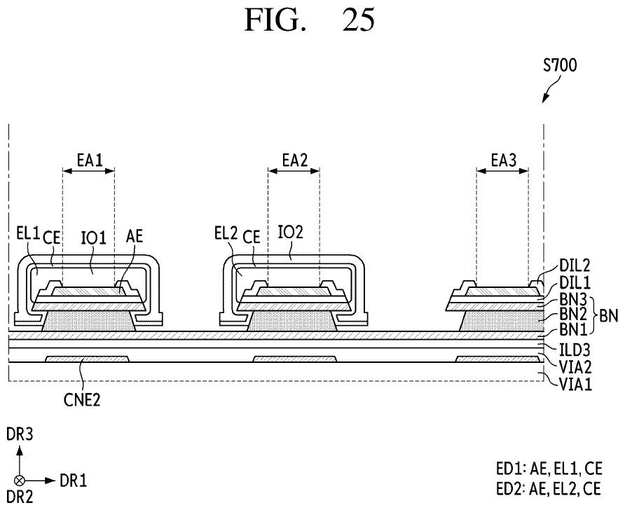

FIGS. 25 to 29 are cross-sectional views for describing operation S700 of FIG. 21.

An operation (S700) of forming a light-emitting element and an element inorganic layer on the bank structure will be described with reference to FIGS. 25 to 29 in addition to FIGS. 1 to 24.

In an embodiment, the operation (S700) of forming the light-emitting element and the element inorganic layer on the bank structure may be similar to the operation (S400) of forming the light-emitting element and the element inorganic layer on the bank structure described with reference to FIGS. 16 to 19. Hereinafter, the common description of the operation (S700) of forming the light-emitting element and the element inorganic layer on the bank structure and the operation (S400) of forming the light-emitting element and the element inorganic layer on the bank structure will be omitted, and the differences thereof will be described later.

By performing the above-described process, a first light-emitting element ED1 and a first element inorganic layer IO1 are formed in a portion overlapping the first light-emitting area EA1, and a second light-emitting element ED2 and a second element inorganic layer IO2 are formed in a portion overlapping the second light-emitting area EA2.

In the process, the anode electrode AE overlapping the third light-emitting area EA3 may be exposed.

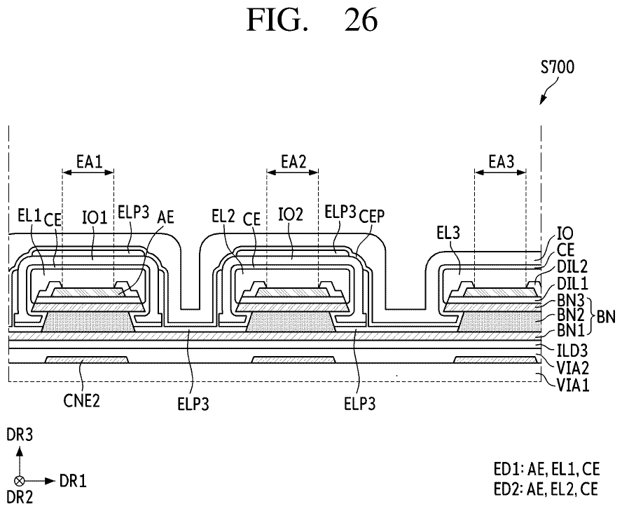

Next, as illustrated in FIG. 26, a third light-emitting layer EL3 and a cathode electrode CE are deposited on the anode electrode AE overlapping the third light-emitting area EA3.

In the process, the process of forming the third light-emitting layer EL3 may be performed through a thermal deposition process. The process of forming the third light-emitting layer EL3 may be performed through entire surface deposition without a separate fine metal mask.

Accordingly, in the process, the material forming the third light-emitting layer EL3 may be formed not only on the anode electrode AE overlapping the third light-emitting area EA3, but may also be disposed on the first element inorganic layer IO1 disposed in the portion overlapping the first light-emitting area EA1 and the second element inorganic layer IO2 disposed in the portion overlapping the second light-emitting area EA2.

In addition, the material forming the third light-emitting layer EL3 may also be formed on the first bank layer BN1. The materials forming the third light-emitting layer EL3 disposed on the first bank layer BN1, the first element inorganic layer IO1, and the second element inorganic layer IO2 may be spaced apart from each other. In the process, the materials forming the third light-emitting layer EL3 disposed on the first bank layer BN1, the first element inorganic layer IO1, and the second element inorganic layer IO2 may be referred to as an organic pattern ELP3.

In the process, the process of forming the cathode electrode CE may be performed through a thermal deposition process or a sputtering process. The redundant descriptions will be omitted.

In the process, the process of forming the cathode electrode CE may be performed through entire surface deposition without a separate fine metal mask. Accordingly, the material forming the cathode electrode CE may be formed not only on the third light-emitting layer EL3 overlapping the third light-emitting area EA3, but may also be disposed on the organic pattern ELP3 disposed on the first bank layer BN1, the organic pattern ELP3 disposed in the portion overlapping the first light-emitting area EA1, and the organic pattern ELP3 disposed in the portion overlapping the second light-emitting area EA2.

For convenience of explanation, the materials forming the cathode electrode CE disposed on the first bank layer BN1, the first element inorganic layer IO1, and the second element inorganic layer IO2 are illustrated as being connected to each other, but the specification is not limited thereto. Depending on the embodiment, the materials forming the cathode electrode CE disposed on the first bank layer BN1, the first element inorganic layer IO1, and the second element inorganic layer IO2 may be spaced apart from each other.

Next, an element inorganic layer IO is formed on the cathode electrode CE. In the process, the element inorganic layer IO may cover all of the materials forming the cathode electrode CE disposed on the first bank layer BN1, the first element inorganic layer IO1, and the second element inorganic layer IO2, in addition to the cathode electrode CE disposed in the portion overlapping the third light-emitting area EA3. The redundant descriptions will be omitted.

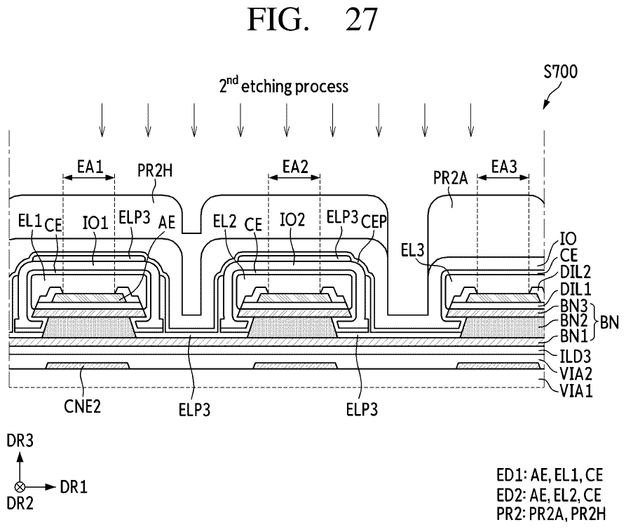

Next, as illustrated in FIG. 27, a photoresist PR2 is formed in the third light-emitting area EA3 and a portion overlapping a periphery of the third light-emitting area EA3, and a second etching process is performed using the photoresist PR2 as a mask. In an embodiment, in the second etching process, a dry etching process and a wet etching process may be alternately performed.

In the process, the photoresist PR2 may include a halftone mask PR2H and a photomask PR2A. The halftone mask PR2H and the photomask PR2A may be spaced apart, and the element inorganic layer IO may be exposed in a portion where the halftone mask PR2H and the photomask PR2A are not formed.

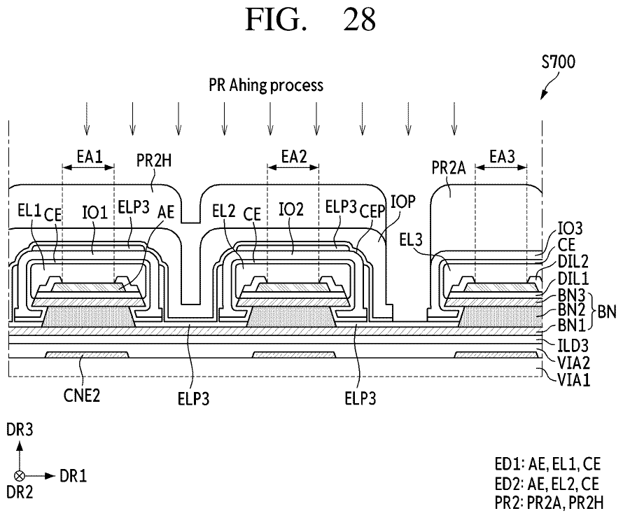

First, the element inorganic layer IO that does not overlap the photoresist PR2 is removed by performing a dry etching process. Through the process, the element inorganic layer IO may be formed as a third element inorganic layer IO3 and an element inorganic pattern IOP, as illustrated in FIG. 28.

Although not illustrated in the drawing, through the process, the cathode electrode CE may be exposed in a portion where the halftone mask PR2H and the photomask PR2A are not formed.

Secondly, the cathode electrode CE that does not overlap the photoresist PR2 is removed by performing a wet etching process. Through the process, the cathode electrode CE may be formed as a cathode electrode CE disposed in a portion overlapping the third light-emitting area EA3 and an electrode pattern CEP spaced apart from the cathode electrode CE. In the process, the organic pattern ELP3 in the portion where the halftone mask PR2H and the photomask PR2A are not formed may be exposed.

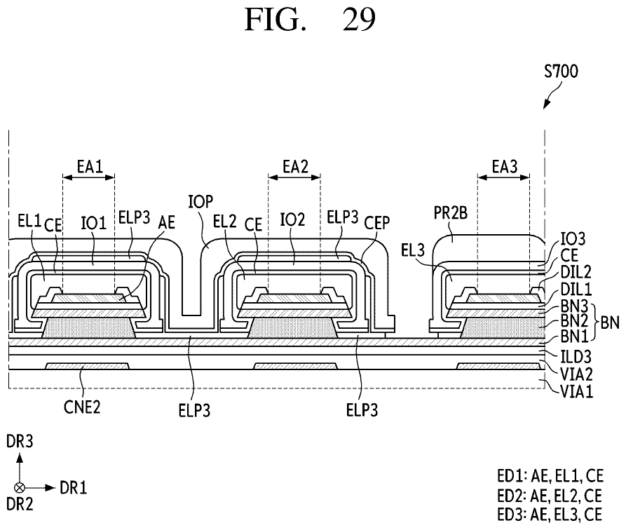

Next, a photoresist PR ashing process is performed. In the process, a portion of the organic pattern ELP3 may be removed, and additionally, the halftone mask PR2H may be completely removed. In the process, the photomask PR2A may be formed in the shape of a photoresist PR2B illustrated in FIG. 29.

In this way, a third light-emitting element ED3 and a third element inorganic layer IO3 may be formed. The third light-emitting element ED3 and the third element inorganic layer IO3 may be covered by the photoresist PR2B.

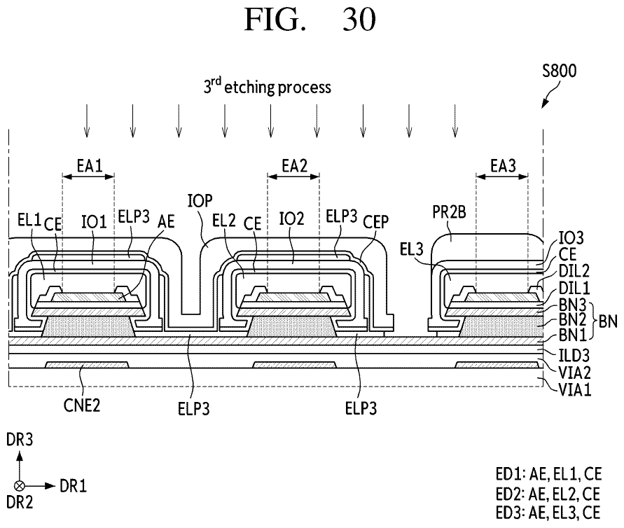

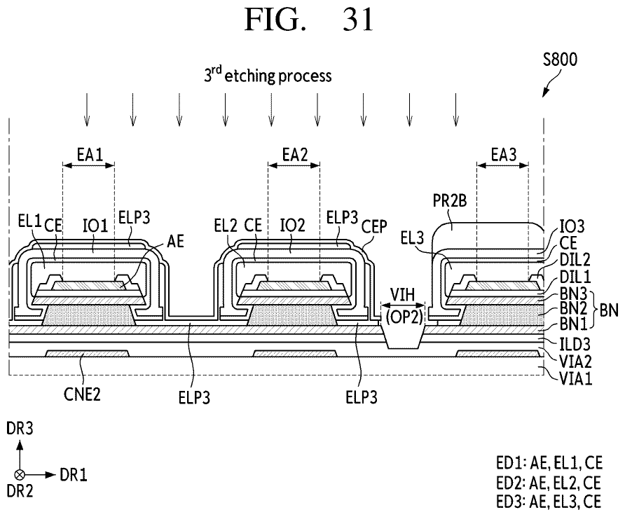

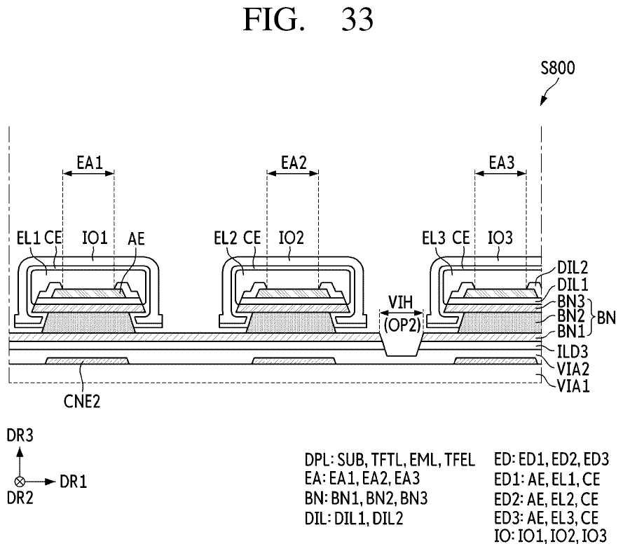

FIGS. 30 to 33 are cross-sectional views for describing operation S800 of FIG. 21.

An operation (S800) of defining a via hole by removing a portion of the bank structure will be described with reference to FIGS. 30 to 33 in addition to FIGS. 1 to 29.

First, a third etching process is performed using the photoresist PR2B as it is. In an embodiment, in the third etching process, a dry etching process and a wet etching process may be alternately performed.

First, a dry etching process is performed to defined a via hole VIH and remove the element inorganic pattern IOP that does not overlap the photoresist PR2B.

In the process, the via hole VIH may be defined by removing the element inorganic pattern IOP and a portion of the first bank layer BN1, the third insulating layer ILD3, and the second via layer VIA2 that do not overlap the photoresist PR2B. In other words, the via hole VIH may be defined to penetrate through the first bank layer BN1 and the third insulating layer ILD3.

Through the process, all of the element inorganic patterns IOP disposed in the portions overlapping the first light-emitting area EA1 and the second light-emitting area EA2 are removed, thereby exposing the electrode pattern CEP.

Secondly, the electrode pattern CEP that does not overlap the photoresist PR2B is removed by performing a wet etching process. Through the process, all of the electrode patterns CEP disposed in the portions overlapping the first light-emitting area EA1 and the second light-emitting area EA2 may be removed, and the organic pattern ELP3 may be exposed.

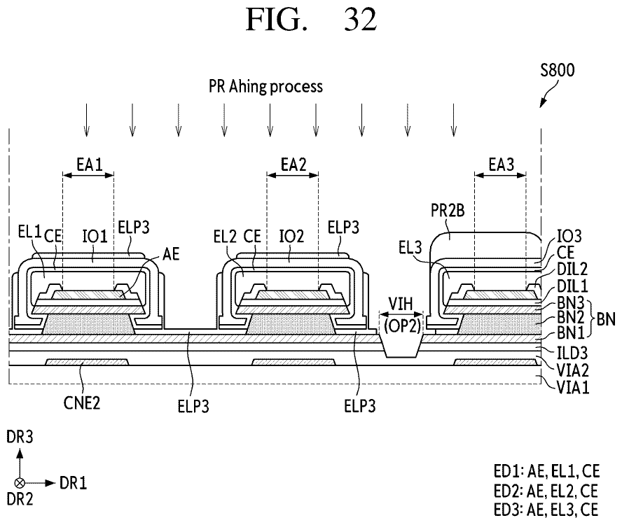

Next, as illustrated in FIG. 32, a photoresist PR ashing process is performed. Through the process, both the organic pattern ELP3 and the photoresist PR2B may be removed.

In this way, the display element layer EML and the via hole VIH defined in the display device 30 may be formed.

Referring back to FIGS. 20 to 33, in the display device 30, the via hole VIH may be defined and the bank structure BN may be formed without a separate additional mask and/or a separate additional photoresist process by the halftone mask PR2H in the fabricating process. Therefore, the display device 30 in an embodiment may have ease of fabrication.

In addition, the display device 30 may be easily fabricated by performing the second etching process and the third etching process using the same photoresist PR2.

In addition, in the display device 30, high-resolution pixels may be efficiently disposed by disposing the light-emitting element ED on the bank structure BN. Therefore, the display device 30 in an embodiment may provide a high-resolution product.

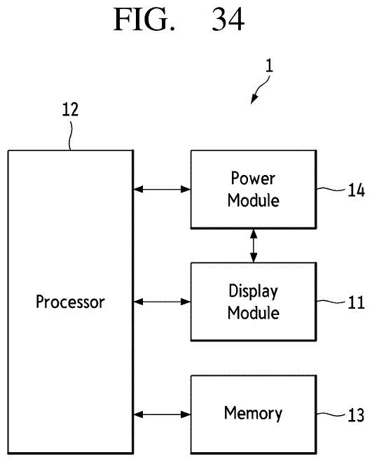

FIG. 34 is a block diagram of an embodiment of an electronic device.

Referring to FIG. 34 in addition to FIGS. 1 to 33, the display devices 10 and 30 in the embodiments may be applied to various electronic devices 1. The electronic device 1 in an embodiment may include the display devices 10 and 30 described above, and may further include a module or device having additional functions in addition to the display devices 10 and 30.

The electronic device 1 in an embodiment may include a display module 11, a processor 12, a memory 13, and a power module 14.

The processor 12 may include at least one of a central processing unit (“CPU”), an application processor (“AP”), a graphic processing unit (“GPU”), a communication processor (“CP”), an image signal processor (“ISP”), and a controller.

Data information desired for an operation of the processor 12 or the display module 11 may be stored in the memory 13. When the processor 12 executes an application stored in the memory 13, image data signals and/or input control signals may be transmitted to the display module 11, and the display module 11 may process the provided signals and output image information through a display screen.

The power module 14 may include a power supply module, such as a power adapter or a battery device, and a power conversion module that converts power supplied by the power supply module to generate power desired for an operation of the electronic device 1.

At least one of the components of the electronic device 1 described above may be included in the display device according to the above-described embodiments. In addition, some of the individual modules functionally included within one module may be included within the display device, while others may be provided separately from the display device. In an embodiment, the display device includes the display module 11, and the processor 12, the memory 13, and the power module 14 may be provided in the form of other devices within the electronic device 1 other than the display device, for example.

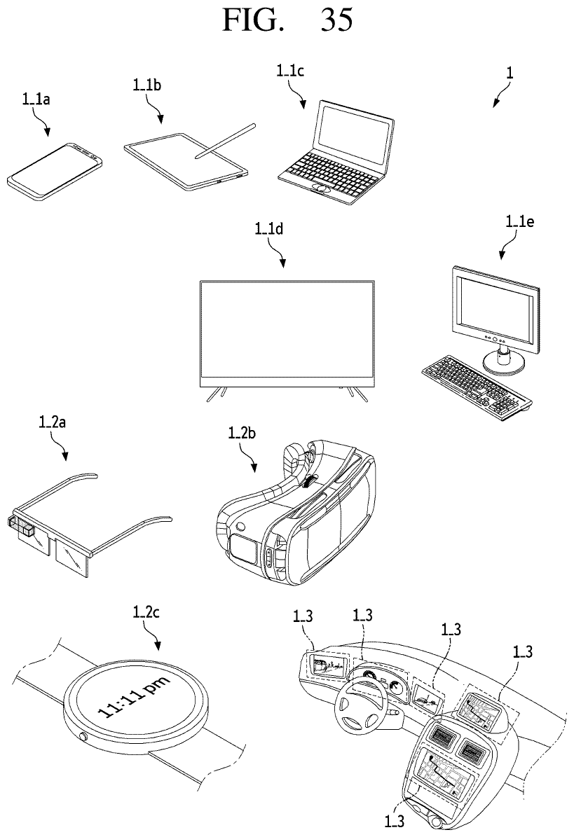

FIG. 35 illustrates schematic diagrams of embodiments of electronic devices.

Referring to FIG. 35, various electronic devices 1 to which the display devices 10 and 30 in the embodiments is applied may include not only an image display electronic device such as a smart phone 1_1a, a tablet PC 1_1b, a laptop 1_1c, a television (“TV”) 1_1d, and a desk monitor 1_1e, but also a wearable electronic device including a display module such as a smart glasses 1_2a, a head mounted display 1_2b, a smart watch 1_2c, or the like, and a vehicle electronic device 1_3 including a display module such as a Center Information Display (“CID”), a room mirror display, etc., disposed on a vehicle's instrument panel, center fascia, or dashboard.

Embodiments of the disclosure should not be construed as being limited to the embodiments set forth herein. Rather, these embodiments are provided so that this disclosure will be thorough and complete and will fully convey the concept of the disclosure to those skilled in the art.

While the disclosure has been particularly shown and described with reference to embodiments thereof, it will be understood by those of ordinary skill in the art that various changes in form and details may be made therein without departing from the spirit or scope of the disclosure as defined by the following claims.

What is claimed is:

1. A display device comprising:
a substrate including a light-emitting area and a non-light-emitting area;
a via layer disposed on the substrate and including an organic material;
a bank structure disposed on the via layer in a portion overlapping the light-emitting area and having an overhang structure;
an element insulating layer disposed on the bank structure and defining a light-emitting opening; and
a first light-emitting element disposed on the element insulating layer and in contact with the bank structure,
wherein a via hole penetrates through a first bank layer of the bank structure in a portion overlapping the non-light-emitting area,
the via hole defines a non-light-emitting opening, and
the via hole exposes the via layer in a portion overlapping the non-light-emitting opening.

2. The display device of claim 1, wherein the bank structure further includes:
a second bank layer disposed on the first bank layer; and
a third bank layer including a tip which protrudes further toward the non-light-emitting area than a side surface of the second bank layer.

3. The display device of claim 2, wherein in a plan view, the first bank layer has a shape of a conductive pattern completely surrounding the non-light-emitting opening.

4. The display device of claim 2, further comprising a second light-emitting element spaced apart from the first light-emitting element,
wherein the second bank layer and the third bank layer overlapping the first light-emitting element and the second bank layer and the third bank layer overlapping the second light-emitting element are spaced apart from each other with the via hole.

5. The display device of claim 4, wherein the second bank layer and the third bank layer overlapping the first light-emitting element and the second bank layer and the third bank layer overlapping the second light-emitting element are electrically connected through the first bank layer.

6. The display device of claim 4, further comprising:
a first element inorganic layer covering the first light-emitting element; and
a second element inorganic layer covering the second light-emitting element,
wherein the first element inorganic layer and the second element inorganic layer are spaced apart from each other with the via hole.

7. The display device of claim 6, further comprising an organic encapsulation layer disposed on the first element inorganic layer and the second element inorganic layer,
wherein the via layer contacts the organic encapsulation layer in a portion overlapping the via hole.

8. The display device of claim 2, wherein the second bank layer includes:
a first surface facing the first bank layer;
a first side surface facing the via hole; and
a second side surface opposite to the first side surface, and
a first inclined angle defined by the first surface and the first side surface and a second inclined angle defined by the first surface and the second side surface are different from each other.

9. The display device of claim 8, wherein the first inclined angle is greater than the second inclined angle.

10. The display device of claim 2, further comprising an insulating layer disposed between the via layer and the bank structure and including an inorganic insulating material,
wherein the via hole penetrates through the insulating layer,
the insulating layer, the first bank layer, and the third bank layer facing the via hole have a regular tapered shape, and
a taper angle of the insulating layer, the first bank layer, and the third bank layer facing the via hole is 60 degrees or more and 80 degrees or less.

11. A method for fabricating a display device, the method comprising:
forming a bank structure including a first bank layer, a second bank layer, and a third bank layer on a substrate including a via layer;
forming a tip of the third bank layer which protrudes further than a side surface of the second bank layer;
forming a light-emitting element and an element inorganic layer on the bank structure; and
defining a via hole by removing a portion of the bank structure,
wherein the via hole penetrates through the first bank layer.

12. The method of claim 11, wherein in the defining the via hole by removing the portion of the bank structure,
the via hole is defined by removing a portion of the first bank layer by a dry etching process.

13. The method of claim 12, wherein in the defining the via hole by removing the portion of the bank structure,
the dry etching process is performed using a halftone mask.

14. The method of claim 11, wherein in the defining the via hole by removing the portion of the bank structure,
in a plan view, a plurality of via holes are formed and each have an island shape.

15. The method of claim 11, wherein in the forming the tip of the third bank layer which protrudes further than the side surface of the second bank layer,
the second bank layer and the third bank layer include different metal materials, and
the second bank layer has a higher etching rate than the first bank layer and the third bank layer.

16. An electronic device comprising:
a display device including a substrate including a light-emitting area and a non-light-emitting area; and
at least one of a display module, a processor, a memory, and a power module connected to the display device, the display device including:
a via layer disposed on the substrate and including an organic material;
a bank structure disposed on the via layer in a portion overlapping the light-emitting area and having an overhang structure;
an element insulating layer disposed on the bank structure and defining a light-emitting opening; and
a first light-emitting element disposed on the element insulating layer and in contact with the bank structure,
wherein a via hole penetrating through a first bank layer of the bank structure in a portion overlapping the non-light-emitting area,
the via hole defines a non-light-emitting opening, and
the via hole exposes the via layer in a portion overlapping the non-light-emitting opening.

17. The electronic device of claim 16, wherein the bank structure further includes:
a second bank layer disposed on the first bank layer; and
a third bank layer including a tip which protrudes further toward the non-light-emitting area than a side surface of the second bank layer.

18. The electronic device of claim 17, wherein in a plan view, the first bank layer has a shape of a conductive pattern completely surrounding the non-light-emitting opening.

19. The electronic device of claim 17, further comprising a second light-emitting element spaced apart from the first light-emitting element,
wherein the second bank layer and the third bank layer overlapping the first light-emitting element and the second bank layer and the third bank layer overlapping the second light-emitting element are spaced apart from each other with the via hole.

20. The electronic device of claim 19, further comprising:
a first element inorganic layer covering the first light-emitting element; and
a second element inorganic layer covering the second light-emitting element,
wherein the first element inorganic layer and the second element inorganic layer are spaced apart from each other with the via hole.
